(19) United States
(12) Patent Application Publication
(10) Pub. No.: US 2017/0077403 A1
(43) Pub. Date: Mar. 16, 2017

(54) METHOD FOR FABRICATING LARGE METAL NANOFIBER ELECTRODE ARRAY USING ALIGNED METAL NANOFIBER

(71) Applicant: POSTECH ACADEMY- INDUSTRY FOUNDATION, Pohang-si (KR)

(72) Inventors: Tae-Woo LEE, Pohang-si (KR); Yeongjun LEE, Pohang-si (KR)

(73) Assignee: POSTECH ACADEMY- INDUSTRY FOUNDATION, Pohang-si (KR)

(21) Appl. No.: 15/110,720

(22) PCT Filed: Jan. 29, 2014
(86) PCT No.: PCT/KR2014/000883

§ 371 Date: Nov. 8, 2016

(30) Foreign Application Priority Data
Jan. 31, 2013 (KR) 10-2013-0011502
Jan. 31, 2013 (KR) 10-2013-0011503
Nov. 22, 2013 (KR) 10-2013-0142934
Nov. 22, 2013 (KR) 10-2013-0142939

(51) Int. Cl. H01L 51/00; H01L 51/52; H01L 51/56; H01L 21/288; H01L 51/05; H01L 29/45; H01L 29/49; H01L 51/44; H01L 51/10

(52) U.S. Cl. CPC H01L 51/0021; H01L 51/441; H01L 51/5209; H01L 51/56; H01L 51/105; H01L 51/5225; H01L 51/055; H01L 29/45; H01L 29/495; H01L 21/288; H01L 2251/301

(57) ABSTRACT

Disclosed is a largescale nanofiber electrode array using aligned metal nanofiber, which includes preparing a metal precursor/organic polymer complex solution, forming an aligned metal/polymer complex nanofiber pattern with a continuously connected shape on a substrate to by injecting the solution with an electric field aided robotic nozzle printer and moving the substrate, and performing thermal treatment on the complex nanofiber pattern to form an aligned nanofiber metal pattern. Accordingly, the position and direction of the metal nanofiber pattern can be accurately controlled, and the metal nanofiber pattern can be aligned in a desired direction.

### TECHNICAL FIELD

The present invention relates to a method of fabricating a nanofiber electrode array, and more particularly, to a method of fabricating the nanofiber electrode array including a metal nanofiber pattern.

### BACKGROUND ART

In future information-oriented society, electronic equipment having high tech functions will be closely related to daily life. In addition, electronic equipment is increasingly reduced in size and weight to provide portability and convenience. Electronic devices having excellent functions and portability are widely used. Further, electronic equipment such as wearable computers will become an essential part of daily life. With increasing demand for such technology, high density integration has become an issue for a long time in the semiconductor and display fields. Accordingly, nanosizing of electronic devices has been become very important. It is important to realize a small transistor in fabricating highly integrated electronic devices. In realizing a small transistor, it is essential to realize an aligned electrode line having high conductivity and a small width.

As representative technologies for forming an electrode line through a solution process, as opposed to vacuum deposition, there are offset printing, inkjet printing, screen printing, etc. Using these methods, an electrode line having a line width of several micrometers or more for a transistor having high conductivity can be fabricated, but it is difficult to realize an electrode having a nanoscale line width.

Other than the solution process, there is an imprinting method as another method of forming a metal pattern. Upon application of an imprinting method, a nanoscale metal pattern may be formed, but a metal should be disadvantageously subjected to a vacuum deposition process.

In addition, the processes have the following problems.

First, offset printing technology is a technology of printing through transfer of a metal ink using a patterned blanket. In the case of the offset printing technology, several micrometer-scale high resolution may be realized depending upon the scale of the blanket pattern, and mass production is possible. However, in this process, it is difficult to manufacture a blanket having a precise pattern and there is a limitation in transferring an ink. In addition, since this method adopts a direct contact manner, a blanket may be disadvantageously damaged or contaminated.

In the case of inkjet printing technology, patterning is carried out by discharging minute ink droplets. Since the inkjet printing technology is a noncontact method, a pattern is not contaminated and a material is less damaged. However, despite the fact that the resolution of a pattern should be determined depending upon the sizes of droplets formed on a substrate, formation of a high-resolution pattern of 10 μm or less is still limited.

A screen-printing method is a process of disposing an ink paste on a screen of a fabric or metal which is tightened by strong tension and then rolling with a squeegee such that an ink is pushed out through a mesh of the screen, thus being transferred. Although the screen-printing method is a contact-type printing method, a substrate is hardly affected by contact and less ink is consumed. However, the resolution depends upon the mesh type of the screen and thus it is difficult to form a pattern of 10 μm or less.

Finally, the imprinting method is a method of forming a pattern using a stamp and heat or UV. By using this method, a high-resolution pattern having a size of 100 nm or less may be formed. However, it is difficult to manufacture a stamp having a precise high-resolution pattern. In addition, upon application of this method, mass productivity is low. Further, since this method is a contact-type method, a stamp may be damaged or contaminated.

### DISCLOSURE

### Technical Problem

Therefore, the present invention has been made in view of the above problems, and it is an object of the present invention to form a nanofiber-shape metal pattern so as to improve a previously limited metal pattern resolution, and to provide a method of fabricating the nanofiber electrode array including such a pattern.

It is another object of the present invention to provide a method of fabricating the nanofiber electrode array including a metal nanofiber pattern so as to simplify a conventional complex fabrication process of a metal electrode array having a minute line width.

### Technical Solution

In accordance with an aspect of the present invention, the above and other objects can be accomplished by the provision of a method of fabricating the nanofiber electrode array including a metal nanofiber pattern. The method may include a step of preparing a metal precursor/organic polymer complex solution by mixing a metal precursor and an organic polymer with distilled water or an organic solvent; a step of forming an aligned metal precursor/organic polymer complex nanofiber pattern with a continuously connected shape on a substrate by injecting the metal precursor/organic polymer complex solution into a nozzle of an electric field aided robotic nozzle printer and applying an electric field thereto and, accordingly, moving the substrate when a solidified nanofiber with a continuously connected shape is charged while perpendicularly discharging the metal precursor/organic polymer complex solution toward the substrate when the metal precursor/organic polymer complex solution forms a Taylor cone at an end of the nozzle; and a step of forming an aligned metal nanofiber pattern composed of the metal nanograins by pyrolyzing the organic polymer through thermal treatment of the aligned metal precursor/organic polymer complex nanofiber pattern and reducing the metal precursor to metal nanograins.

Here, in the step of preparing the metal precursor/organic polymer complex solution, the metal precursor and the organic polymer in a weight ratio of 10:90 to 97:3 may be dissolved in distilled water or an organic solvent such that a concentration becomes 1% by weight to 50% by weight. Upon the discharging of the metal precursor/organic polymer complex solution, the solution may be discharged from a distance of 10 μm to 20 mm perpendicular to the substrate.

In addition, the step of forming an aligned metal precursor/organic polymer complex nanofiber pattern may be performed by means of an electric field aided robotic nozzle printer, wherein the electric field aided robotic nozzle printer may include:

i) a storage device containing a metal precursor/organic polymer complex solution;

ii) a nozzle for discharging a solution supplied from the storage device;

iii) a voltage application device for applying a high voltage to the nozzle;

iv) a collector for fixing the substrate;

v) a robot stage for horizontally moving the collector;

vi) a micro distance controller for perpendicularly moving the collector; and

vii) a base plate for supporting the collector.

In addition, the voltage applied to the electric field aided robotic nozzle printer may be 0.1 kV to 30 kV.

In addition, the substrate may include at least one selected from the group consisting of an insulating material, a metal material, a carbon material, and a complex material including a conductor and an insulating film.

In addition, the metal precursor may include at least one selected from the group consisting of a copper precursor, a titanium precursor, an aluminum precursor, a silver precursor, a platinum precursor, a nickel precursor, and a gold precursor.

Here, the copper precursor may include at least one selected from the group consisting of copper acetate, copper acetate hydrate, copper acetylacetonate, copper i-butyrate, copper carbonate, copper chloride, copper chloride hydrate, copper ethylacetoacetate, copper 2-ethylhexanoate, copper fluoride, copper formate hydrate, copper gluconate, copper hexafluoroacetylacetonate, copper hexafluoroacetylacetonate hydrate, copper methoxide, copper neodecanoate, copper nitrate hydrate, copper nitrate, copper perchlorate hydrate, copper sulfate, copper sulfate hydrate, copper tartrate hydrate, copper trifluoroacetylacetonate, copper trifluoromethanesulfonate, and tetraamminecopper sulfate hydrate.

In addition, the titanium precursor may include at least one selected from the group consisting of titanium carbide, titanium chloride, titanium ethoxide, titanium fluoride, titanium hydride, titanium nitride, titanium isopropoxide, titanium propoxide, titanium methoxide, titanium oxyacetylacetonate, titanium 2-ethylhexyloxide, and titanium butoxide.

In addition, the aluminum precursor may include at least one selected from the group consisting of aluminum chloride, aluminum fluoride, aluminum hexafluoroacetylacetonate, aluminum chloride hydrate, aluminum nitride, aluminum trifluoromethanesulfonate, triethylaluminum, aluminum acetylacetonate, aluminum hydroxide, aluminum lactate, aluminum nitrate hydrate, aluminum 2-ethylhexanoate, aluminum perchlorate hydrate, aluminum sulfate hydrate, aluminum ethoxide, aluminum carbide, aluminum sulfate, aluminum acetate, aluminum acetate hydrate, aluminum sulfide, aluminum hydroxide hydrate, aluminum phenoxide, aluminum fluoride hydrate, aluminum tributoxide, aluminum diacetate, aluminum diacetate hydroxide, and aluminum 2,4-pentanedionate.

In addition, the silver precursor may include at least one selected from the group consisting of silver hexafluorophosphate, silver neodecanoate, silver nitrate, silver trifluoromethanesulfonate, silver acetate, silver carbonate, silver chloride, silver perchlorate, silver tetrafluoroborate, silver trifluoroacetate, silver 2-ethylhexanoate, silver fluoride, silver perchlorate hydrate, silver lactate, silver acetylacetonate, silver methanesulfonate, silver heptafluorobutyrate, silver chlorate, silver pentafluoropropionate, and silver hydrogenfluoride.

In addition, the platinum precursor may include at least one selected from the group consisting of chloroplatinic acid hexahydrate, dihydrogen hexahydroxyplatinate, platinum acetylacetonate, platinum chloride, platinum chloride hydrate, platinum hexafluoroacetylacetonate, tetraammineplatinum chloride hydrate, tetraammineplatinum hydroxide hydrate, tetraammineplatinum nitrate, tetraammineplatinum tetrachloroplatinate, tetrachlorodiammine platinum, dichlorodiammine platinum, and diammineplatinum dichloride.

In addition, the nickel precursor may include at least one selected from the group consisting of hexaamminenickel chloride, nickel acetate, nickel acetate hydrate, nickel acetylacetonate, nickel acetylacetonate hydrate, nickel carbonyl, nickel chloride, nickel chloride hydrate, nickel fluoride, nickel fluoride hydrate, nickel hexafluoroacetylacetonate hydrate, nickel hexafluoroacetylacetonate, nickel hydroxide, nickel hydroxyacetate, nickel nitrate hydrate, nickel perchlorate hydrate, nickel perchlorate, nickel sulfate hydrate, nickel sulfate, nickel tetrafluoroborate hydrate, nickel tetrafluoroborate, nickel trifluoroacetylacetonate hydrate, nickel trifluoroacetylacetonate, nickel trifluoromethanesulfonate, nickel peroxide hydrate, nickel peroxide, nickel octanoate hydrate, nickel carbonate, nickel sulfamate hydrate, nickel sulfamate, and nickel carbonate hydroxide hydrate.

In addition, the gold precursor may include at least one selected from the group consisting of chlorocarbonylgold, hydrogen tetrachloroaurate, hydrogen tetrachloroaurate hydrate, chlorotriethylphosphinegold, chlorotrimethylphosphinegold, dimethyl (acetylacetonate)gold, gold (I) chloride, gold cyanide, gold sulfide, and gold chloride hydrate.

In addition, in the step of preparing the metal precursor/organic polymer complex solution, the metal precursor/organic polymer complex solution may further include an auxiliary metal precursor.

The auxiliary metal precursor may include at least one selected from the group consisting of a copper precursor, a titanium precursor, an aluminum precursor, a silver precursor, a platinum precursor, a nickel precursor, and a gold precursor.

The organic polymer may include at least one selected from the group consisting of polyvinylalcohol (PVA), polyvinylacetate (PVAc), poly(p-phenylene vinylene (PPV), polyhydroxyethylmethacrylate (pHEMA), polyethylene oxide (PEO), polystyrene (PS), polycaprolactone (PCL), polyacrylonitrile (PAN), poly(methyl methacrylate) (PMMA), polyimide, poly(vinylidene fluoride) (PVDF), polyaniline (PANI), polyvinylchloride (PVC), nylon, polyacrylic acid, polychlorostyrene, polydimethylsiloxane, polyetherimide, polyethersulfone, polyalkylacrylate, polyethylacrylate, polyethylvinylacetate, polyethyl-co-vinylacetate, polyethyleneterephthalate, polylactic acid-co-glycolic acid, polymethacrylate, polymethylstyrene, polystyrenesulfonate, polystyrenesulfonylfluoride, polystyrene-co-acrylonitrile, polystyrene-co-butadiene, polystyrene-co-divinylbenzene, polylactide, polyacrylamide, polybenzimidazole, polycarbonate, polydimethylsiloxane-co-polyethyleneoxide, polyetheretherketone, polyethylene, polyethyleneimine, polyisoprene, polylactide, polypropylene, polysulfone, polyurethane, polyvinylpyrrolidone (PVP), polyphenylenevinylene (PPV), and polyvinylcarbazole (PVK).

In addition, the organic solvent may include at least one selected from the group consisting of dichloroethylene, trichloroethylene, chloroform, chlorobenzene, dichlorobenzene, styrene, dimethylformamide, dimethylsulfoxide, xylene, toluene, cyclohexene, isopropyl alcohol, ethanol, methanol, tetrahydrofuran, isopropylalcohol, terpineol, ethyleneglycol, diethyleneglycol, polyethyleneglycol, acetonitrile, and acetone.

In addition, the step of forming the aligned metal nanofiber pattern by heat-treating the aligned metal precursor/organic polymer complex nanofiber pattern may be carried out at 50° C. to 900° C. for 5 minutes to 8 hours.

In addition, in the step of forming the aligned metal nanofiber pattern by heat-treating the aligned metal precursor/organic polymer complex nanofiber pattern, the heat treatment may be carried out one to five times.

In addition, in the step of forming the aligned metal nanofiber pattern by heat-treating the aligned metal precursor/organic polymer complex nanofiber pattern, the heat treatment may be carried out in air or in a gas atmosphere including at least one selected from the group consisting of oxygen, nitrogen, hydrogen, and argon.

In addition, the metal nanofiber may have a diameter of 10 nm to 3000 nm.

In addition, the metal precursor/organic polymer complex nanofiber pattern may be horizontally aligned.

In accordance with another aspect of the present invention, there is provided an organic or inorganic field-effect transistor including the aforementioned nanofiber electrode array. Such a field-effect transistor may include a gate electrode, a gate insulating layer, a source electrode, a drain electrode, and an organic or inorganic semiconductor layer. Here, any one electrode of the gate electrode, source electrode, and drain electrode is a metal nanofiber electrode fabricated by the aforementioned method of fabricating the metal nanofiber electrode array.

In accordance with still another aspect of the present invention, there is provided an organic light-emitting diode including the aforementioned nanofiber electrode array. Such an organic light-emitting diode includes a positive electrode, a light emitting layer, and a negative electrode, wherein the organic light-emitting diode selectively, further includes an auxiliary electrode layer, a hole injection layer, a hole transport layer, an electron transport layer, an exciton blocking layer, a hole blocking layer, or an electron injection layer, and at least one of the positive and negative electrodes has a grid array of a metal nanofiber electrode fabricated by the method of fabricating a metal nanofiber electrode array.

In accordance with yet another aspect of the present invention there is provided an organic solar cell including the aforementioned nanofiber electrode array. Such an organic solar cell includes a positive electrode, a light emitting layer, and a negative electrode, wherein the organic light-emitting diode selectively, further includes an auxiliary electrode layer, a hole injection layer, a hole transport layer, an electron transport layer, an exciton blocking layer, a hole blocking layer, or an electron injection layer, and at least one of the positive and negative electrodes has a grid array of a metal nanofiber electrode fabricated by the method of fabricating a metal nanofiber electrode array.

### Advantageous Effects

In accordance with a method of fabricating the nanofiber electrode array including a metal nanofiber pattern of the present invention, the position and direction of the metal nanofiber pattern can be accurately controlled and the metal nanofiber pattern can be aligned in a desired direction.

Accordingly, a metal nanofiber electrode array having an improved metal electrode pattern resolution can be provided.

In addition, a rapid and simplified metal nanofiber electrode array fabrication method can be provided.

### DESCRIPTION OF DRAWINGS

FIG. 1 illustrates a flowchart showing a fabrication method according to an embodiment of the present invention.

FIG. 2 illustrates a schematic diagram of an electric field aided robotic nozzle printer.

FIGS. 3A through 3C illustrate the scanning electron microscope (SEM) images and FIG. 3D illustrates an EDS ingredient analysis result of a copper precursor/organic polymer complex nanofiber according to Fabrication Example 1 of the present invention.

FIGS. 4A through 4C illustrate the scanning electron microscope (SEM) images and FIG. 4D illustrates an EDS ingredient analysis result of a copper oxide nanofiber according to Fabrication Example 1 of the present invention.

FIGS. 5A through 5C illustrate the scanning electron microscope (SEM) images and FIG. 5D illustrates an EDS ingredient analysis result of a copper nanofiber according to Fabrication Example 1 of the present invention.

FIG. 6 includes a graph (a) and a table (b) showing data values of the widths and resistivity of a copper nanofiber according to Fabrication Example 1 of the present invention, and moving speeds of a collector.

FIG. 7 includes a graph (a) and a table (b) showing the change in the resistivity value of a copper nanofiber according to Fabrication Example 1 of the present invention in accordance with heat treatment conditions.

FIG. 8 includes a graph (a) and a table (b) showing the uniformity of a copper nanofiber according to Fabrication Example 1 of the present invention.

FIGS. 9A through 9C illustrate SEM images of a silver precursor-copper precursor/organic polymer complex nanofiber according to Fabrication Example 2 of the present invention.

FIGS. 10A through 10C illustrate SEM images of a silver-copper nanofiber according to Fabrication Example 2 of the present invention.

FIG. 11 includes a graph (a) and a table (b) showing an IV characteristic curve and the resistivity of a silver-copper nanofiber according to Fabrication Example 2 of the present invention.

FIG. 12 illustrates a schematic fabrication diagram of an organic field-effect transistor according to another embodiment of the present invention.

FIG. 13 illustrates images of an organic field-effect transistor according to another embodiment of the present invention.

FIG. 14 is a graph showing the transfer curve characteristic of an organic field-effect transistor according to Fabrication Example 5 of the present invention.

FIG. 15 is a graph showing an IV characteristic curve of an organic field-effect transistor according to Fabrication Example 5 of the present invention.

### MODES OF THE INVENTION

Hereinafter, the present invention will be described in detail by describing exemplary embodiments of the invention with reference to the attached drawings. However, the scope of the present invention is not limited to the embodiments described in the present specification and may be embodied in other forms. Like reference numerals indicate like elements throughout the specification. In the specification, the expression, “aligned” nanofiber, refers to a nanofiber, the position and direction of which may be controlled according to a desired objective. The cross sections of metal patterns obtained according to conventional offset printing, inkjet printing, screen printing, or imprinting method have a wide rectangle, but the cross section of a nanofiber pattern according to the present invention may have a circular, oval, or semicircular shape. Unlike metal nanowires with a single crystal shape and a length of several micrometers or less fabricated according to conventional chemical synthesis and deposition, a polycrystalline nanofiber, in which nanograins are connected to each other by printing, is fabricated and, upon application of a roll-to-roll process, a pattern may be fabricated to a desired length. For example, a pattern may be prepared to a length of 1 micrometer or more, preferably 1 mm to 100 meters.

In addition, the term, “horizontally” aligned, as used in the present specification refers to horizontal alignment with respect to a substrate.

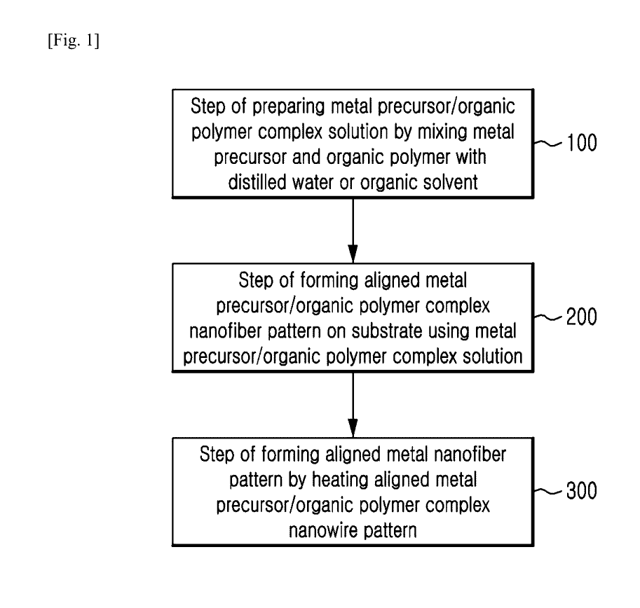

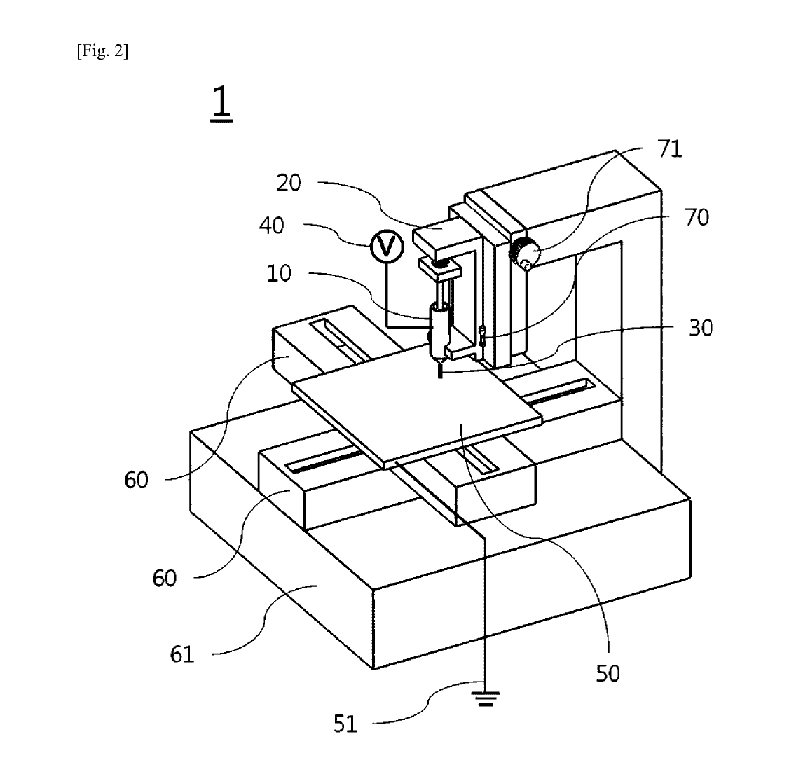

FIG. 1 illustrates a flowchart showing a fabrication method according to an example of the present invention.

First, a metal precursor and an organic polymer are mixed with distilled water or an organic solvent to prepare a metal precursor/organic polymer complex solution (S100).

The metal precursor/organic polymer complex solution including the metal precursor and the organic polymer in a weight ratio of 10:90 to 97:3 may be dissolved in distilled water or an organic solvent such that a concentration becomes particularly 1% by weight to 50% by weight. More particularly, the weight ratio may be 70:30 to 90:10.

When the metal precursor and the organic polymer are mixed within this range, a finally obtained metal nanofiber may have a uniform diameter without breaking.

The organic polymer is pyrolyzed by a heat treatment step described below. Accordingly, the proportion of the organic polymer is greater than 90% by weight, and the amount of a metal nanofiber remaining after the heat treatment is deficient, and thus, a wire might not be uniformly formed and may break.

In addition, when the proportion of the organic polymer is less than 3% by weight, the viscosity of the metal precursor/organic polymer complex solution is extremely decreased and thus the formation of a metal precursor/organic complex nanofiber pattern by means of an electric field aided robotic nozzle printer described below might not be satisfactorily performed.

The concentration of the metal precursor/organic polymer complex solution may be 1% by weight to 30% by weight. When a mix ratio of the metal precursor to an organic polymer is included within the aforementioned ratio and the concentrations of the metal precursor and organic polymer complex solution are within the aforementioned ratio, the viscosity of the solution is sufficient, and thus, a metal precursor/organic polymer complex nanofiber pattern may be formed by means of an electric field aided robotic nozzle printer.

In the metal precursor/organic polymer complex solution, viscosity is too low when the concentration of a solute with respect to a solvent is less than 1% by weight, and thus, a droplet-shaped solution may be formed, instead of a nanofiber.

In addition, when the concentration of the metal precursor/organic polymer complex solution is greater than 30% by weight, viscosity is too high, and thus, a solution might not be satisfactorily discharged by an electric field aided robotic nozzle printer described below.

Here, the metal precursor may include at least one selected from the group consisting of a copper precursor, a titanium precursor, an aluminum precursor, a silver precursor, a platinum precursor, a nickel precursor, and a gold precursor.

The copper precursor may include at least one selected from the group consisting of copper acetate, copper acetate hydrate, copper acetylacetonate, copper i-butyrate, copper carbonate, copper chloride, copper chloride hydrate, copper ethylacetoacetate, copper 2-ethylhexanoate, copper fluoride, copper formate hydrate, copper gluconate, copper hexafluoroacetylacetonate, copper hexafluoroacetylacetonate hydrate, copper methoxide, copper neodecanoate, copper nitrate hydrate, copper nitrate, copper perchlorate hydrate, copper sulfate, copper sulfate hydrate, copper tartrate hydrate, copper trifluoroacetylacetonate, copper trifluoromethanesulfonate, and tetraamminecopper sulfate hydrate, but the present invention is not limited thereto.

The titanium precursor may include at least one selected from the group consisting of titanium carbide, titanium chloride, titanium ethoxide, titanium fluoride, titanium hydride, titanium nitride, titanium isopropoxide, titanium propoxide, titanium methoxide, titanium oxyacetylacetonate, titanium 2-ethylhexyloxide, and titanium butoxide, but the present invention is not limited thereto.

The aluminum precursor may include at least one selected from the group consisting of aluminum chloride, aluminum fluoride, aluminum hexafluoroacetylacetonate, aluminum chloride hydrate, aluminum nitride, aluminum trifluoromethanesulfonate, triethylaluminum, aluminum acetylacetonate, aluminum hydroxide, aluminum lactate, aluminum nitrate hydrate, aluminum 2-ethylhexanoate, aluminum perchlorate hydrate, aluminum sulfate hydrate, aluminum ethoxide, aluminum carbide, aluminum sulfate, aluminum acetate, aluminum acetate hydrate, aluminum sulfide, aluminum hydroxide hydrate, aluminum phenoxide, aluminum fluoride hydrate, aluminum tributoxide, aluminum diacetate, aluminum diacetate hydroxide, and aluminum 2,4-pentanedionate, but the present invention is not limited thereto.

The silver precursor may include at least one selected from the group consisting of silver hexafluorophosphate, silver neodecanoate, silver nitrate, silver trifluoromethanesulfonate, silver acetate, silver carbonate, silver chloride, silver perchlorate, silver tetrafluoroborate, silver trifluoroacetate, silver 2-ethylhexanoate, silver fluoride, silver perchlorate hydrate, silver lactate, silver acetylacetonate, silver methanesulfonate, silver heptafluorobutyrate, silver chlorate, silver pentafluoropropionate, and silver hydrogenfluoride, but the present invention is not limited thereto.

The platinum precursor may include at least one selected from the group consisting of chloroplatinic acid hexahydrate, dihydrogen hexahydroxyplatinate, platinum acetylacetonate, platinum chloride, platinum chloride hydrate, platinum hexafluoroacetylacetonate, tetraammineplatinum chloride hydrate, tetraammineplatinum hydroxide hydrate, tetraammineplatinum nitrate, tetraammineplatinum tetrachloroplatinate, tetrachlorodiammine platinum, dichlorodiammine platinum, and diammineplatinum dichloride, but the present invention is not limited thereto.

The nickel precursor may include at least one selected from the group consisting of hexaamminenickel chloride, nickel acetate, nickel acetate hydrate, nickel acetylacetonate, nickel acetylacetonate hydrate, nickel carbonyl, nickel chloride, nickel chloride hydrate, nickel fluoride, nickel fluoride hydrate, nickel hexafluoroacetylacetonate hydrate, nickel hexafluoroacetylacetonate, nickel hydroxide, nickel hydroxyacetate, nickel nitrate hydrate, nickel perchlorate hydrate, nickel perchlorate, nickel sulfate hydrate, nickel sulfate, nickel tetrafluoroborate hydrate, nickel tetrafluoroborate, nickel trifluoroacetylacetonate hydrate, nickel trifluoroacetylacetonate, nickel trifluoromethanesulfonate, nickel peroxide hydrate, nickel peroxide, nickel octanoate hydrate, nickel carbonate, nickel sulfamate hydrate, nickel sulfamate, and nickel carbonate hydroxide hydrate, but the present invention is not limited thereto.

The gold precursor may include at least one selected from the group consisting of chlorocarbonylgold, hydrogen tetrachloroaurate, hydrogen tetrachloroaurate hydrate, chlorotriethylphosphinegold, chlorotrimethylphosphinegold, dimethyl (acetylacetonate)gold, gold (I) chloride, gold cyanide, gold sulfide, and gold chloride hydrate, but the present invention is not limited thereto.

In addition, the organic polymer may include at least one selected from the group consisting of polyvinylalcohol (PVA), polyvinylacetate (PVAc), poly(p-phenylene vinylene (PPV), polyhydroxyethylmethacrylate (pHEMA), polyethylene oxide (PEO), polystyrene (PS), polycaprolactone (PCL), polyacrylonitrile (PAN), poly(methyl methacrylate) (PMMA), polyimide, poly(vinylidene fluoride) (PVDF), polyaniline (PANI), polyvinylchloride (PVC), nylon, polyacrylic acid, polychlorostyrene, polydimethylsiloxane, polyetherimide, polyethersulfone, polyalkylacrylate, polyethylacrylate, polyethylvinylacetate, polyethyl-co-vinylacetate, polyethyleneterephthalate, polylactic acid-co-glycolic acid, polymethacrylate, polymethylstyrene, polystyrenesulfonate, polystyrenesulfonylfluoride, polystyrene-co-acrylonitrile, polystyrene-co-butadiene, polystyrene-co-divinylbenzene, polylactide, polyacrylamide, polybenzimidazole, polycarbonate, polydimethylsiloxane-co-polyethyleneoxide, polyetheretherketone, polyethylene, polyethyleneimine, polyisoprene, polylactide, polypropylene, polysulfone, polyurethane, polyvinylpyrrolidone (PVP), polyphenylenevinylene (PPV), and polyvinylcarbazole (PVK).

In addition, the organic solvent may include at least one selected from the group consisting of dichloroethylene, trichloroethylene, chloroform, chlorobenzene, dichlorobenzene, styrene, dimethylformamide, dimethylsulfoxide, xylene, toluene, cyclohexene, isopropyl alcohol, ethanol, methanol, tetrahydrofuran, isopropylalcohol, terpineol, ethyleneglycol, diethyleneglycol, polyethyleneglycol, acetonitrile, and acetone.

Here, the metal precursor/organic polymer complex solution may further include an auxiliary metal precursor. When the auxiliary metal precursor is further included, a nanofiber including one or more metals may be formed, and thus, a nanofiber exhibiting various metallic characteristics may be formed.

The auxiliary metal precursor may include at least one selected from the group consisting of a copper precursor, a titanium precursor, an aluminum precursor, a silver precursor, a platinum precursor, a nickel precursor, and a gold precursor.

Particular examples of such copper precursor, titanium precursor, aluminum precursor, silver precursor, platinum precursor, nickel precursor, and gold precursor are the same as those described with respect to the metal precursor, and thus, a particular description thereof is omitted.

The metal precursor/organic complex nanofiber pattern is aligned on the substrate using the metal precursor/organic polymer complex solution (S200).

For example, an aligned metal precursor/organic polymer complex nanofiber pattern with a continuously connected shape may be formed on the substrate by injecting the metal precursor/organic polymer complex solution into a nozzle of an electric field aided robotic nozzle printer and applying an electric field thereto and, accordingly, moving a substrate when a solidified nanofiber with a continuously connected shape is charged while perpendicularly discharging the metal precursor/organic polymer complex solution toward the substrate when the metal precursor/organic polymer complex solution forms a Taylor cone at an end of the nozzle.

More particularly, a metal precursor/organic polymer complex nanofiber pattern horizontally aligned on the substrate may be formed while horizontally moving the substrate.

Here, a material of the substrate may include at least one selected from the group consisting of an insulating material, a metal material, a carbon material, a polymer material, and a conductor/insulating film complex material, but the present invention is not limited thereto.

In particular, the insulating material may be, for example, a glass plate, a plastic film, paper, fabric, wood, etc. The metal material may be a metal, for example, aluminum, titanium, gold, silver, stainless steel, etc., may be used, but the present invention is not limited thereto.

In addition, the carbon material may be graphene, carbon nanotubes, graphite, amorphous carbon, etc. The polymer material may be a PET film, a PDMS film, a polyimide film, a polycarbonate film, etc.

In addition, the conductor/insulating film complex material may be a semiconductor wafer substrate, a silicon (Si)/silicon dioxide (SiO₂) substrate, a silicon (Si)/silicon nitride (SiN) substrate, an aluminum (Al)/aluminum oxide (Al₂O₃) substrate, etc., but the present invention is not limited thereto.

Here, the metal precursor/organic complex nanofiber pattern is formed while the solution is discharged from a distance of 10 μm to 20 mm perpendicular to the substrate.

With an increasing distance between the discharge site of the metal precursor/organic polymer complex solution, and the substrate, an alignment speed of the pattern in a horizontal direction increases while the metal precursor/organic polymer complex solution is discharged, and thus, it is difficult to form the pattern in or in parallel with a desired direction.

However, in the present invention, the metal precursor/organic polymer complex solution is discharged at a distance of 10 μm to 20 mm from the substrate, and thus, the pattern may be aligned in a desired direction.

Here, the step of forming the aligned metal precursor/organic complex nanofiber pattern is performed by means of an electric field aided robotic nozzle printer.

The electric field aided robotic nozzle printer includes: i) a storage device containing a metal precursor/organic polymer complex solution; ii) a nozzle for discharging a solution supplied from the storage device; iii) a voltage application device for applying a high voltage to the nozzle; iv) a collector for fixing the substrate; v) a robot stage for horizontally moving the collector; vi) a micro distance controller for perpendicularly moving the collector; and vii) a base plate, which is disposed under the collector, for supporting the collector.

FIG. 2 illustrates a schematic diagram of the electric field aided robotic nozzle printer.

Referring to FIG. 2, the electric field aided robotic nozzle printer particularly includes a storage device 10, a discharge regulator 20, a nozzle 30, a voltage application device 40, a collector 50, a robot stage 60, a base plate 61, and a micro distance controller 70.

The storage device 10 is provided to store the metal precursor/organic polymer complex solution and to supply the solution to the nozzle 30 such that the solution is discharged from the nozzle 30.

The storage device 10 may have a syringe shape. The material of the storage device 10 may be plastic, glass, stainless steel, etc.

A storage capacity of the storage device 10 may be selected within a range of about 1 μl to about 5,000 ml, preferably within a range of about 10 μl to about 50 ml.

When the storage device 10 is made of stainless steel, the storage device 10 may include a gas inlet for injecting gas (not shown), and thus, the solution may be discharged to the outside of the storage device using gas pressure.

Meanwhile, a plurality of storage devices 10 may be provided to form a metal precursor/organic complex nanofiber having a core/shell structure.

The discharge regulator 20 is provided to apply pressure to the solution in the storage device 10 so that the metal/organic polymer complex solution in the storage device 10 is discharged through the nozzle 30.

As the discharge regulator 20, a pump or a gas pressure regulator may be used.

The discharge regulator 20 may control a discharge speed of the solution within a range of 1 nl/min to 50 ml/min.

When the storage devices 10 are used, the discharge regulator 20 is provided for each of the storage devices 10 and may be independently operated.

When the storage device 10 is made of stainless steel, the discharge regulator 20 may be a gas pressure regulator (not shown).

The nozzle 30 is provided to discharge some of the metal precursor/organic polymer complex solution supplied from the storage device 10. The discharged solution may forms droplets at an end of the nozzle 30. The nozzle 30 may have a diameter of about 1 μm to about 1.5 mm.

The nozzle 30 may include a single nozzle, a dual-concentric nozzle, or a triple-concentric nozzle.

When a metal precursor/organic complex nanofiber with a core/shell structure is formed, two or more organic solution types may be discharged by means of the dual-concentric nozzle or the triple-concentric nozzle. In this case, two or three storage devices 10 may be connected to the dual-concentric or the triple-concentric nozzle.

The voltage application device 40 is provided to apply a high voltage to the nozzle 30, and may include a high-voltage generation device.

The voltage application device 40 may be electrically connected to the nozzle 30 via, for example, the storage device 10.

The voltage application device 40 may apply a voltage of about 0.1 kV to about 30 kV. An electric field is present between the nozzle 30, to which a high voltage is applied by the voltage application device 40, and the collector 50, which is grounded, droplets formed at an end of the nozzle 30 form a Taylor cone due to the electric field, and a nanofiber is continuously formed at the end thereof.

A nanofiber formed of the solution discharged from the nozzle 30 is aligned and attached to the collector 50. The collector 50 has a planar shape and may be horizontally moved by the robot stage 60. The collector 50 is grounded to have a relative grounding characteristic with respect to a high voltage applied to the nozzle 30.

Reference number 51 illustrates that the collector 50 is grounded. The collector 50 may be made of a conductive material, for example, a metal, and may have a flatness of 0.5 μm to 10 μm (the flatness represents a maximum tolerance value from a completely horizontal surface when the flatness of the surface is 0).

The robot stage 60 is provided to move the collector 50. The robot stage 60 is driven by a servomotor and thus may be moved at a precise speed.

The robot stage 60 may be controlled to be moved, for example, in two directions, X- and Y-axes, on a horizontal surface.

A moving distance of the robot stage 60 may be 100 nm or more and 100 cm or less. For example, the moving distance may be 10 μm or more and 20 cm or less.

A moving speed of the robot stage 60 may be 1 mm/min to 60,000 mm/min.

The robot stage 60 may be installed on the base plate 61 and may have a flatness of 0.5 μm to 5 μm. Here, a distance between the nozzle 30 and the collector 50 may be constantly controlled by the flatness of the base plate 61.

The base plate 61 suppresses vibration occurring due to the operation of the robot stage, and thus, precision of the metal precursor/organic complex nanofiber pattern may be controlled.

The micro distance controller 70 is provided to control a distance between the nozzle 30 and the collector 50. The distance between the nozzle 30 and the collector 50 may be controlled when the micro distance controller 70 perpendicularly moves the storage device 10 and the nozzle 30.

The micro distance controller 70 may be constituted of a jog 71 and a micrometer 72. The jog 71 may be used to approximately adjust a distance in units of mm or cm. The micrometer 72 may be used for fine distance adjustment of at least 10 μm.

The distance between the nozzle 30 and the collector 50 may be accurately adjusted by means of the micrometer 72 after disposing the nozzle 30 closely to the collector 50 by means of the jog 71.

By using the micro distance controller 70, the distance between the nozzle 30 and the collector 50 may be adjusted to within a range of 10 μm to 20 mm.

A three-dimensional path of a nanofiber electrospun from the nozzle may be represented by the following equations (see D. H. Reneker, A. L. Yarin, H. Fong, S. Koombhongse, “Bending instability of electrically charged liquid jets of polymer solutions in electrospinning” J. Appl. Phys., 87, 9, 4531-4546 (2000)).

As represented by Equations (1a) and (1b) below, perturbations in the metal precursor/organic complex nanofiber increase with increasing distance between the collector and the nozzle:

$$\begin{matrix}x = {10}^{- 3} L cos ( \frac{2 π}{λ} z ) \frac{h - z}{h} , and & Equation ( 1 a ) \\ y = {10}^{- 3} L sin ( \frac{2 π}{λ} z ) \frac{h - z}{h} . & Equation ( 1 b )\end{matrix}$$

In the equations, x and y respectively represent the positions in X- and Y-axis directions on a horizontal surface with respect to the collector, L is a constant representing a length scale, λ represents a perturbation wavelength, z represents a perpendicular position of the nanofiber with respect to the collector (z=0), and h represents a distance between the nozzle and the collector.

From Equations (1a) and (1b), it can be confirmed that, when z is the same, x and y representing the perturbations of the nanofiber increase as a distance, h, between the collector and the nozzle increases.

For example, the collector 50 parallel to an x-y plane may be moved on an x-y plane by the robot stage 60, and a distance between the nozzle 30 and the collector 50 may be adjusted in a Z-axis direction by the micro distance controller 70.

An electric field aided robotic nozzle printer 1 according to an example of the present invention may reduce a distance between the nozzle 30 and the collector 50 to a scale of ten to several tens of micrometers and thus the nanofiber may be linearly dropped onto the collector 50 before the nanofiber is perturbed, whereby an elaborate nanofiber pattern may be formed by the movement of the collector 50.

By forming the metal precursor/organic polymer complex nanofiber through the movement of the collector, a perturbation variable of an organic wire pattern is decreased, compared the case in which a nozzle moves. Accordingly, a more precise metal precursor/organic polymer complex nanofiber pattern may be formed.

Meanwhile, the electric field aided robotic nozzle printer 100 may be disposed inside a housing.

The housing may be made of a transparent material. The housing may be sealed and a gas may be injected into the interior of the housing via a gas inlet (not shown). The injected gas may be nitrogen, dry air, etc. Due to the gas injection, the metal precursor/organic polymer complex solution easily oxidized due to moisture may be stably maintained.

In addition, a ventilator and a lamp may be installed in the housing. The ventilator controls steam pressure in the housing such that an evaporation rate of a solvent may be controlled when a formed nanofiber is discharged. In the case of robotic nozzle printing requiring rapid evaporation of a solvent, the speed of the ventilator is adjusted and thus evaporation of a solvent may be facilitated. The evaporation rate of the solvent affects the morphological, and electrical characteristics of the metal precursor/organic complex nanofiber. When the evaporation rate of the solvent is too high, the solution is dried up at an end of the nozzle before the nanofiber of the metal precursor/organic complex is formed and thus the nozzle is blocked. When the evaporation rate of the solvent is too low, a solid-type nanofiber of the metal precursor/organic polymer complex is not formed and a liquid-type nanofiber is formed on the collector. The liquid-type metal precursor/organic polymer complex solution does not have the excellent electrical characteristics of the nanofiber and thus cannot be used in fabricating devices.

Since the evaporation rate of the solvent affects the formation of the nanofiber as described above, the ventilator plays an important role in formation of the nanofiber.

In particular, the process of aligning the metal precursor/organic polymer complex nanofiber using the electric field aided robotic nozzle printer 100 includes i) a step of supplying the metal precursor/organic polymer complex solution to the storage device and ii) a step of discharging the metal precursor/organic polymer solution from the nozzle while applying a high voltage to the nozzle through the voltage application device of the electric field aided robotic nozzle printer. In addition, when the metal precursor/organic polymer complex solution is discharged from the nozzle, the process includes moving the collector, which is disposed on the substrate, in a horizontal direction.

In an example of the present invention, when the solution including a metal precursor and an organic polymer is contained in a syringe 10 and then discharged from the nozzle 30 by a syringe pump 20, droplets are formed at an end of the nozzle 30. When a voltage of 0.1 kV to 30 kV is applied to the nozzle 30 using a high-voltage generator 40, a Taylor cone is formed at an end of the nozzle 30 due to the electrostatic force between electric charge formed at the droplets and the collector 50. Droplets do not drop down dropwise and spread, rather, a solvent is volatilized while the cross sections thereof are extended into a circular fiber shape in an electric field direction, and a long connected solid-type nanofiber is attached to the substrate on the collector 50.

Here, with increasing amount of droplets, a metal precursor/organic polymer complex nanofiber, wherein the length of droplets in one direction is longer than that of droplets in another direction, may be formed. The diameter of the metal precursor/organic polymer complex nanofiber may be controlled to several nanometers to micrometers by adjusting an application voltage and the size of the nozzle.

The metal precursor/organic polymer complex nanofiber formed from a charged substance discharged from the nozzle 30 may be aligned on the substrate on the collector 50. Here, by adjusting a distance between the nozzle 30 and the collector 50 to 10 μm to 20 mm. The metal precursor/organic polymer complex nanofiber is formed in a separated shape, not an entangled shape, on the substrate of the collector 50. Here, a distance between the nozzle 30 and the collector 50 may be adjusted by means of the micro distance controller 70.

As such, the metal precursor/organic polymer complex nanofiber may be formed in a desired direction and in a desired number on a desired site of the substrate by minutely moving the collector 50 by means of the micro distance controller 70 and the micrometer 72.

Here, the metal precursor/organic polymer complex nanofiber may be horizontally aligned. Accordingly, the metal precursor/organic complex nanofiber pattern may be horizontally aligned.

Finally, an aligned metal nanofiber pattern is formed by heat-treating the aligned metal precursor/organic polymer complex nanofiber pattern (S300).

That is, the organic polymer is pyrolyzed by heat-treating the aligned metal precursor/organic polymer complex nanofiber pattern, and the metal precursor is reduced into metal nanograins, thereby forming an aligned metal nanofiber pattern composed of the metal nanograins.

In the step of forming an aligned metal nanofiber pattern by heat-treating the aligned metal precursor/organic polymer complex nanofiber pattern, the heat-treating may be performed at 50° C. to 900° C. for five minutes to eight hours.

Here, the heat-treating is preferably performed by means of a device allowing overall uniform heating, such as a furnace, a vacuum hot plate, a rapid thermal processing device, or a chemical vapor deposition (CVD) chamber, in air or in a specific gas atmosphere, but the present invention is not limited thereto.

In addition, when the heat-treating is performed within the temperature and time ranges, the most uniform crystals are formed and thus electric charge transfer is improved.

When the heat-treating is performed at less than 50° C., the organic polymer is not satisfactorily pyrolyzed and thus it may be difficult to form the metal nanofiber. When the heat-treating is performed at greater than 900° C., it may be difficult to form a uniform nanofiber.

In addition, when the heat-treating is performed for less than five minutes, the time for pyrolyzation of the organic polymer is not sufficient and thus it may be difficult to form the metal nanofiber. When the heat-treating is performed for greater than eight hours, the nanofiber may be deformed due to long heating and thus it may be difficult to form a uniform nanofiber.

The step of forming the aligned metal nanofiber pattern by heat-treating the aligned metal precursor/organic polymer complex nanofiber pattern may be performed one to five times.

Here, when the heat-treating is performed less than once, the organic polymer is not pyrolyzed and thus the metal nanofiber is not formed. When the heat-treating is performed greater than five times, the nanofiber may be deformed and thus it may be difficult to form a uniform nanofiber.

In addition, in the step of forming the aligned metal nanofiber pattern by heat-treating the aligned metal precursor/organic polymer complex nanofiber pattern, the heat-treating may be performed in air or in a gas atmosphere including at least one selected from the group consisting of oxygen, nitrogen, hydrogen, and argon.

When the heat-treating is performed in air or in a gas atmosphere including at least one selected from the group consisting of oxygen, nitrogen, hydrogen, and argon, the metal precursor/organic polymer complex nanofiber may be effectively reduced into a metal nanofiber.

Here, the metal nanofiber may have a diameter of 10 nm to 3000 nm. Here, the diameter may be adjusted depending upon a ratio of the metal precursor and the organic polymer and the concentrations thereof.

In addition, when the metal nanofiber has a diameter of 10 nm to 3000 nm, the metal nanofiber has high conductivity.

Meanwhile, conventional metal nanowires have been fabricated through solution synthesis or growth mechanism. The lengths of metal nanowires fabricated according to such a method were only several micrometers or less. On the other hand, according to the present invention characterized by fabricating a nanofiber by printing the metal precursor/organic polymer complex solution, the nanofiber may be lengthily fabricated without limitation as to the length thereof. Particularly, upon application of a roll-to-roll process, one strand of a continuous long nanofiber applicable to a large-area may be fabricated.

Hereinafter, an organic or inorganic semiconductor-based field-effect transistor including the metal nanofiber electrode array according to an example of the present invention is described in detail.

Such a field-effect transistor may include a gate electrode, a gate insulating layer, a source electrode and a drain electrode, and a semiconductor layer. Here, at least one of the gate electrode, the source electrode, and the drain electrode is a metal nanofiber electrode fabricated according to the aforementioned method of fabricating the metal nanofiber electrode array.

The structure of the transistor may be classified according to the location of the gate electrode. In a bottom gate structure, the gate electrode is located on the substrate, while, in a top gate structure, the gate electrode is located on the substrate. In addition, the structure of the transistor may be classified according to the location of the source/drain electrode. In a bottom contact, the source/drain electrode is located under the semiconductor layer, while, in a top contact structure, the source/drain electrode is located on the semiconductor layer.

For example, a bottom gate-bottom contact device may include a gate insulating layer located on the gate electrode, source and drain electrodes located on the gate insulating layer, and an organic semiconductor layer, which contacts the source and drain electrodes, on the gate insulating layer.

In the case of a metal nanofiber, only one strand of a metal nanofiber can substitute for at least one of source, drain, and gate electrodes. Accordingly, when a transistor is fabricated into a large-area array, resolution may be increased and an overlapping area between the gate electrode and the source/drain electrode may be greatly reduced.

Here, the semiconductor layer may be an organic or inorganic semiconductor layer.

Examples of the organic semiconductor include a conjugated small molecule, an oligomer, and a polymer semiconductor. For example, the organic semiconductor may include pentacene, tetracene, TIPS-pentacene, polythiophene and derivatives thereof, polyfluorene and derivatives thereof, polyacetylene and derivatives thereof, and polyphenylene and derivatives thereof, but the present invention is not limited thereto.

The inorganic semiconductor includes any inorganic semiconductor, all non-organic substances, such as a crystal of Group IV, such as silicon (Si) or germanium, a compound of Groups III-V, such as gallium arsenide (GaAs), a compound of Groups II-VII, such as CdS, a carbon nanotube composed of only carbon, or graphene.

Meanwhile, since the metal nanofiber electrode array fabricated according to the aforementioned method of fabricating the metal nanofiber electrode array is a continuously connected nanofiber, one end of the metal nanofiber electrode array is cut to be applied to the source and drain electrodes of the organic field-effect transistor according to the present invention, thus completing a device.

Accordingly, by utilizing the metal nanofiber electrode array according to the present invention as the source and drain electrodes of the organic field-effect transistor, an improved device having high field-effect hole mobility may be provided, compared to a transistor in which a metal film electrode is used as source and drain electrodes.

In the case of the transistor array, only one strand of a metal nanofiber can function as an electrode. However, in the case of sheet devices such as an organic light-emitting diode and an organic solar cell, one strand of a metal nanofiber is not sufficient for forming an electrode and thus the metal nanofiber should have a grid shape wherein metal nanofibers intersect.

In addition, to address the above problem, the present invention provides an organic light-emitting diode including the aforementioned nanofiber electrode array with a grid shape as an electrode.

Such an organic light-emitting diode may include a positive electrode, a light emitting layer, and a negative electrode. Here, at least one of the positive and negative electrodes is a metal nanofiber electrode with a grid array fabricated according to the aforementioned method of fabricating the metal nanofiber electrode array.

In addition, the organic light-emitting diode may further include at least one of a hole injection layer, a hole transport layer, an electron transport layer, an exciton blocking layer, a hole blocking layer, and an electron injection layer.

In addition, an auxiliary electrode, such as a conductive polymer (e.g., PEDOT:PSS), may be further included to reduce surface unevenness of the metal nanofiber electrode grid.

In addition, to address the above problem, the present invention provides an organic solar cell including the aforementioned nanofiber electrode array with a grid shape as an electrode.

Such an organic solar cell may include a positive electrode, a photoactive layer, and a negative electrode. Here, at least one of the positive and negative electrodes is a metal nanofiber electrode with a grid array fabricated according to the aforementioned method of fabricating the metal nanofiber electrode array.

In addition, at least one of a hole extraction layer, an exciton blocking layer, and an electron extraction layer may be further included.

In addition, an auxiliary electrode, such as a conductive polymer (e.g., PEDOT:PSS), may be further included to reduce the surface unevenness of the metal nanofiber electrode grid

Now, the present invention will be described in more detail with reference to the following preferred examples. These examples are provided for illustrative purposes only and should not be construed as limiting the scope and spirit of the present invention.

### Fabrication of Copper Nanofiber Electrode Array

### Fabrication Example 1

A copper precursor (25% by weight) and polyvinyl pyrrolidone (PVP) (10% by weight) were dissolved in dimethylformamide and tetrahydrofuran to prepare a copper precursor/PVP solution. The concentration of a resultant copper precursor/PVP solution was 31% by weight.

The prepared copper precursor/PVP solution was contained in a syringe of an electric field aided robotic nozzle printer, and discharged from a nozzle while applying a voltage of about 0.5 kV to a nozzle.

An aligned copper precursor/PVP complex nanofiber pattern was formed on a substrate of a collector moved by a robot stage.

Here, the diameter of the used nozzle was 100 μm, a distance between the nozzle and the collector was 7 mm, and an application voltage was 0.5 kV.

A movement interval in a Y-axis direction of a robot stage was 200 μm and a movement interval in an X-axis direction thereof was 15 cm.

The size of the collector was 20 cm×20 cm and the size of the substrate on the collector was 7 cm×7 cm.

The substrate was a silicon (Si) wafer coated with a silicon oxide film (SiO₂) to a thickness of 300 nm.

When the aligned copper precursor/PVP nanofiber pattern was heat-treated at 350° C. to 500° C. for one or two hours in air by means of a furnace, the PVP organic polymer was pyrolyzed and, at the same time, the copper precursor was oxidized, thereby forming an aligned copper oxide nanofiber composed of copper oxide nanograins.

Subsequently, heat treatment was performed for one or two hours in a 300° C. CVD chamber, in which hydrogen gas was flowed at flow rate of 100 sccm to reduce the copper oxide nanograins into copper nanograins, thereby forming an aligned copper nanofiber pattern composed of copper nanograins.

Accordingly, a copper nanofiber electrode array having an area of 7 cm×7 cm was fabricated using the method of fabricating a large-area nanofiber electrode array.

Analysis of Characteristics of Copper Nanofiber Electrode Array

To analyze the electrical characteristics of the copper nanofiber formed on the SiO₂/Si substrate (the silicon wafer formed by coating a silicon oxide film to a thickness of 300 nm), gold was thermally evaporated on the copper nanofiber using a metal shadow mask, and then IV characteristics thereof were analyzed using a probe station.

Morphological analysis was performed using a scanning electron microscope and ingredient analysis was performed using EDS. In addition, the resistivity of the copper nanofiber electrode fabricated on the substrate was measured.

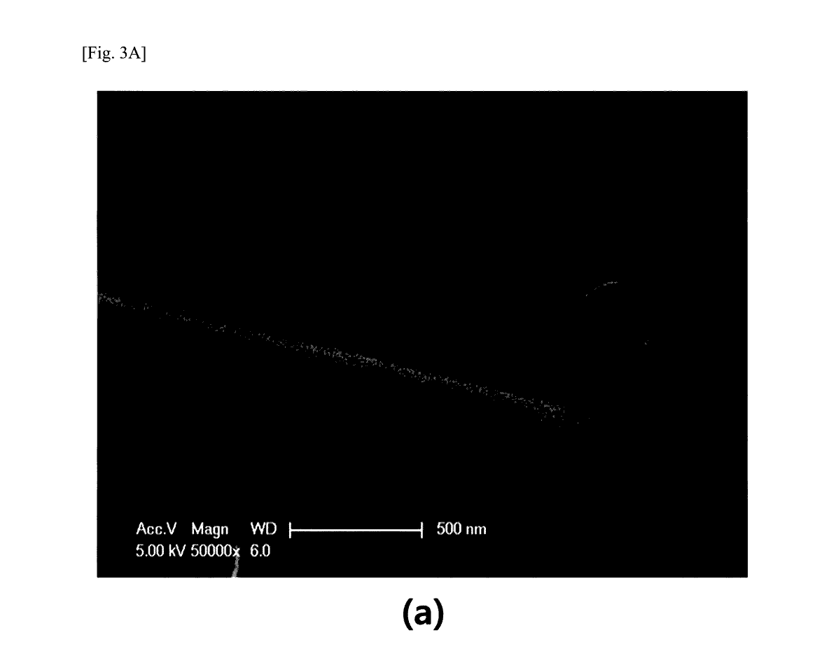

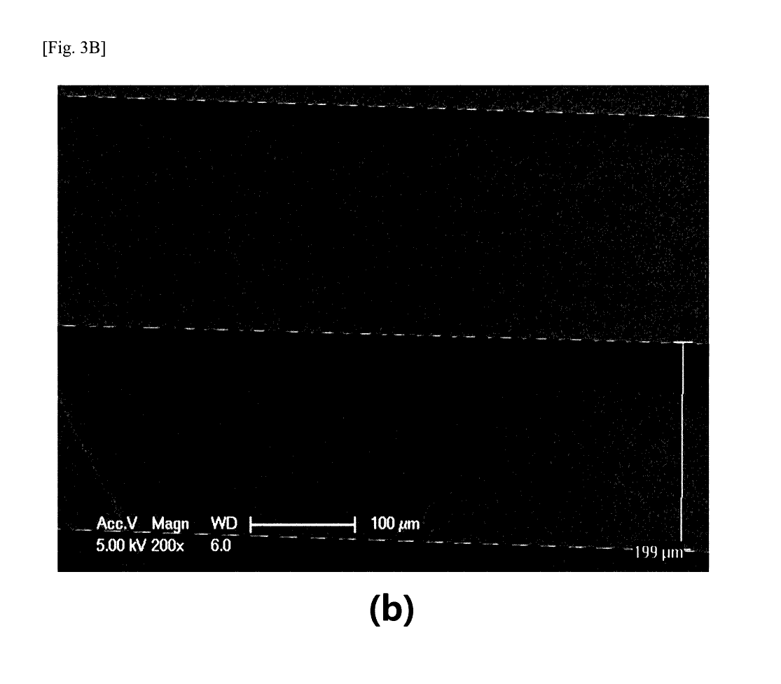

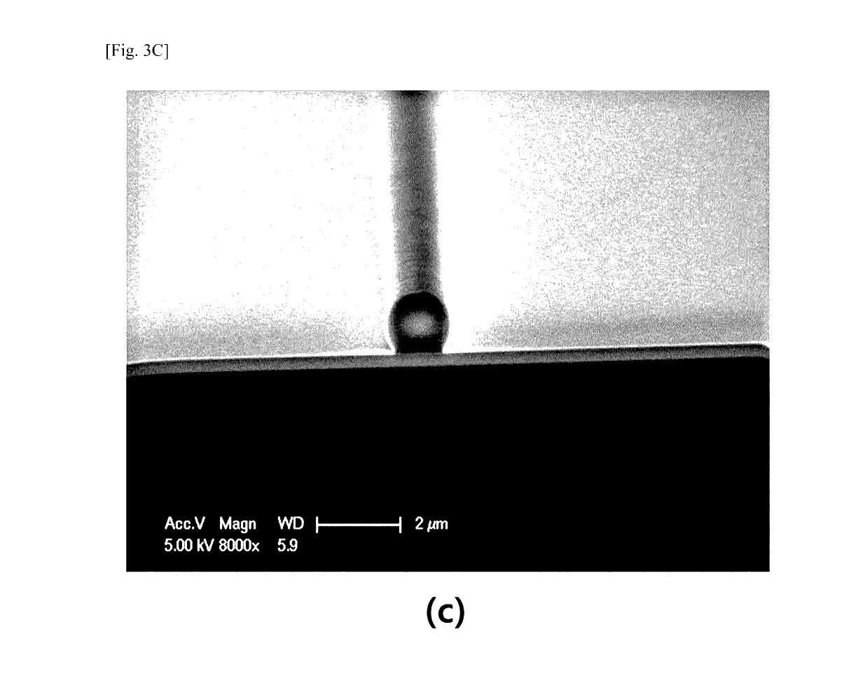

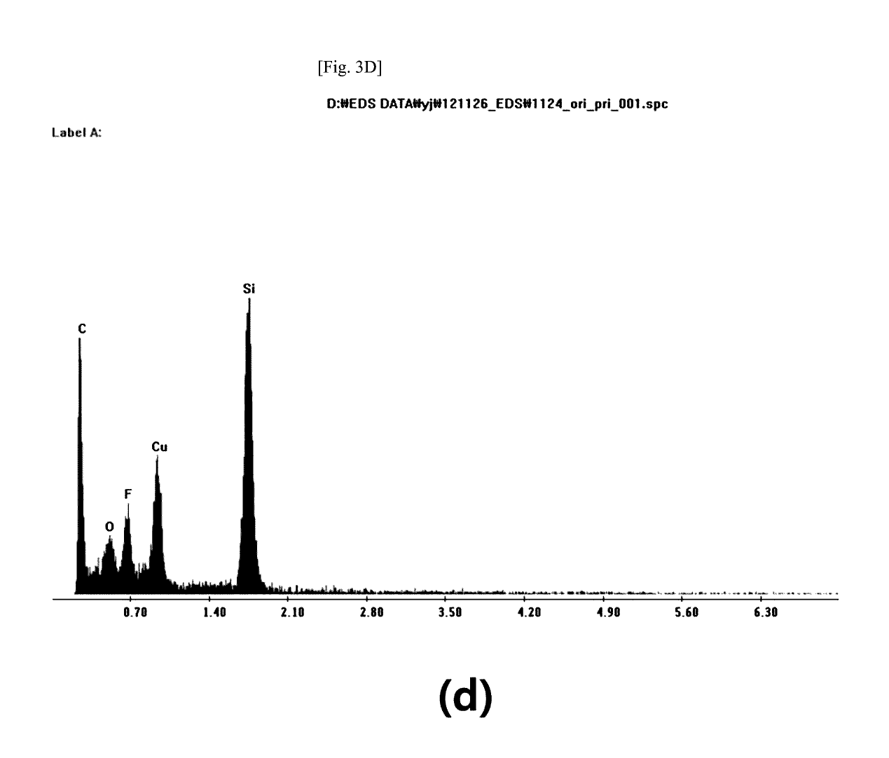

FIG. 3 illustrates the scanning electron microscope (SEM) images and an EDS ingredient analysis result of a copper precursor/organic polymer complex nanofiber according to Fabrication Example 1 of the present invention.

FIG. 3a illustrates an SEM image of the copper precursor/organic polymer complex nanofiber, FIG. 3b illustrates a photograph of the copper precursor/organic polymer complex nanofiber array according to the fabrication example of the present invention, and FIG. 3c illustrates a cross section of the copper precursor/organic polymer complex nanofiber. In addition, FIG. 3d illustrates an EDS analysis result.

Referring to FIG. 3a, it can be confirmed that the copper precursor/organic polymer complex nanofiber according to Fabrication Example 1 of the present invention is uniformly formed in a straight line shape. Referring to FIG. 3b, it can be confirmed that the copper precursor/organic polymer complex nanofiber electrode array according to Fabrication Example 1 of the present invention is uniformly aligned in a horizontal direction. Referring to FIG. 3c, it can be confirmed that the cross section of the copper precursor/organic polymer complex nanofiber according to Fabrication Example 1 of the present invention is uniform. Referring to FIG. 3d, it can be confirmed that the nanofiber according to Fabrication Example 1 of the present invention includes copper.

As a result, it can be confirmed that the copper precursor/organic polymer complex nanofiber according to the fabrication example of the present invention is uniformly aligned and formed in a straight line shape.

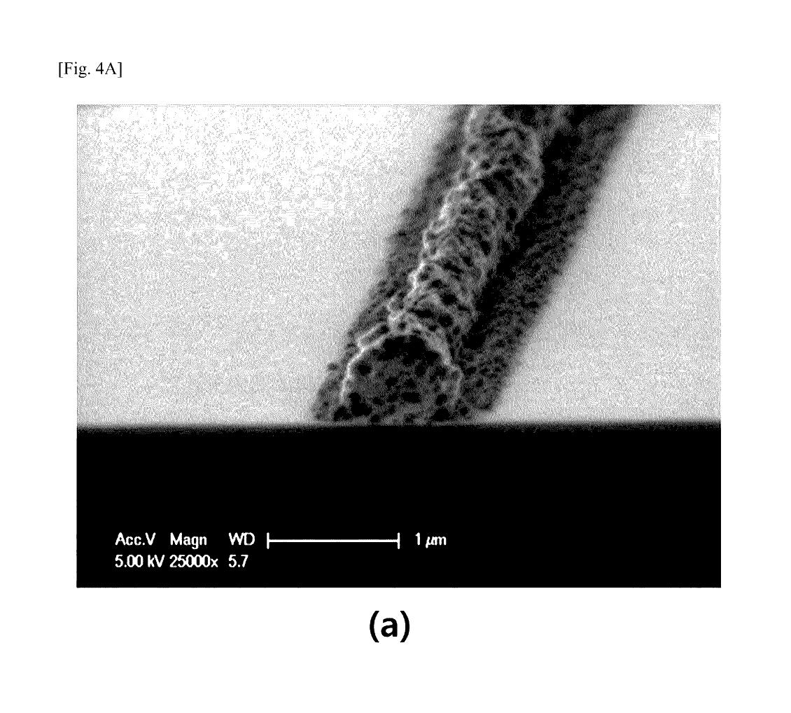

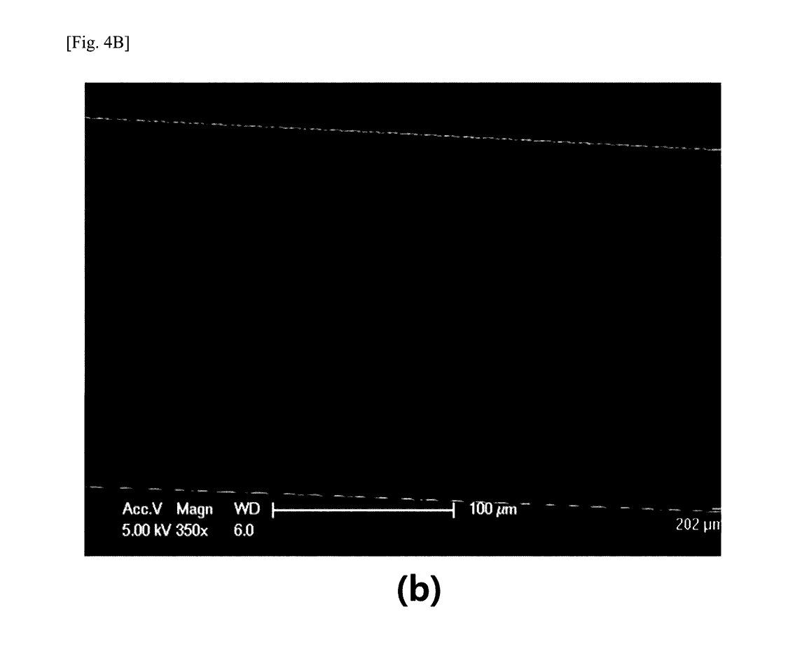

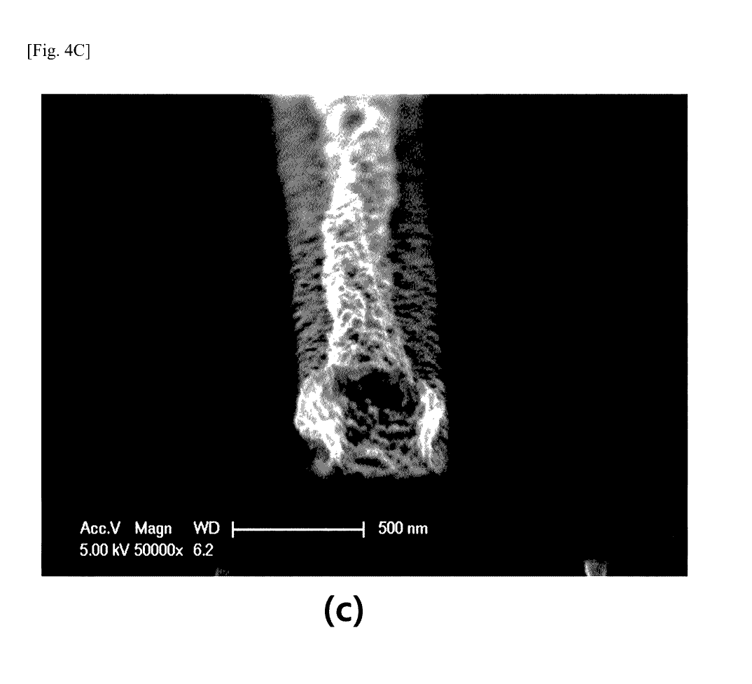

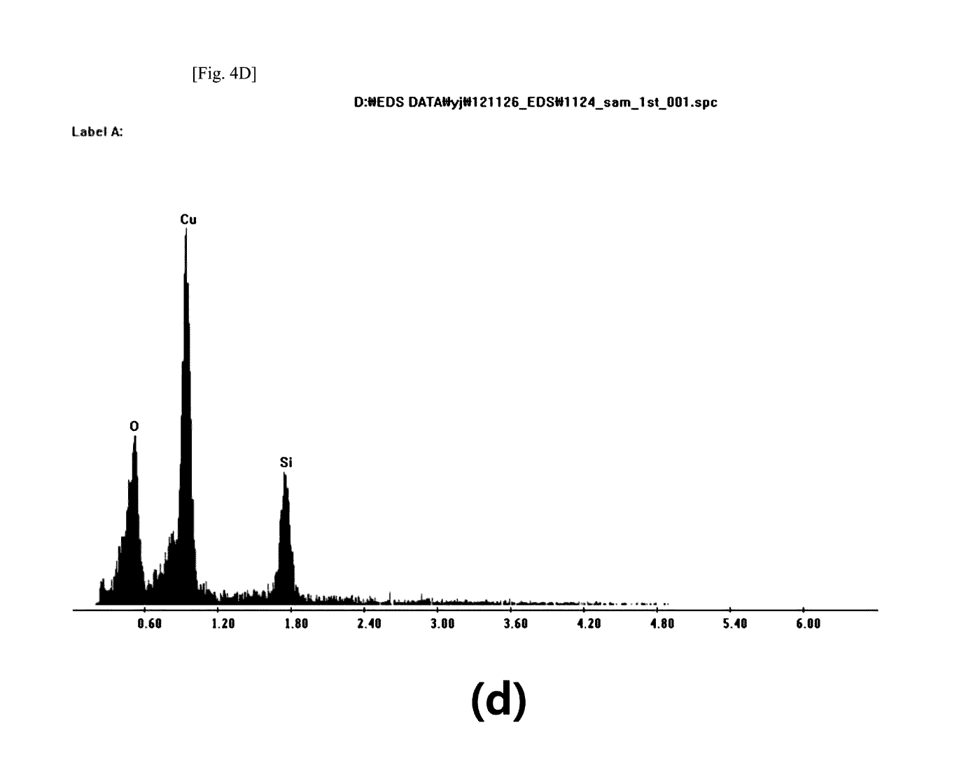

FIG. 4 illustrates the scanning electron microscope (SEM) images and an EDS ingredient analysis result of a copper oxide nanofiber according to Fabrication Example 1 of the present invention.

FIG. 4 illustrates the scanning electron microscope images and an EDS ingredient analysis result of the copper oxide nanofiber formed by heat-treating the copper precursor/organic polymer complex nanofiber for two hours in air by means of a 450° C. furnace.

FIG. 4a illustrates an SEM image of the copper oxide nanofiber, FIG. 4b illustrates an SEM image of the copper oxide nanofiber electrode array according to the fabrication example of the present invention, and FIG. 4c is an SEM image illustrating a cross section of the copper oxide nanofiber. In addition, FIG. 4d illustrates an EDS analysis result.

Referring to FIG. 4a, it can be confirmed that the copper oxide nanofiber according to Fabrication Example 1 of the present invention is uniformly formed in a straight line shape. Referring to FIG. 4b, it can be confirmed that the copper oxide nanofiber electrode array according to Fabrication Example 1 of the present invention is uniformly aligned in a horizontal direction. Referring to FIG. 4c, it can be confirmed that the cross section of a copper oxide nanofiber according to Fabrication Example 1 of the present invention is uniform. Referring to FIG. 4d, it can be confirmed that the nanofiber according to Fabrication Example 1 of the present invention has large peaks at the positions of copper and oxygen. From such peaks, it can be confirmed that a copper oxide nanofiber is formed.

As a result, it can be confirmed that the copper oxide nanofiber according to Fabrication Example 1 of the present invention is uniformly aligned and formed in a straight line shape.

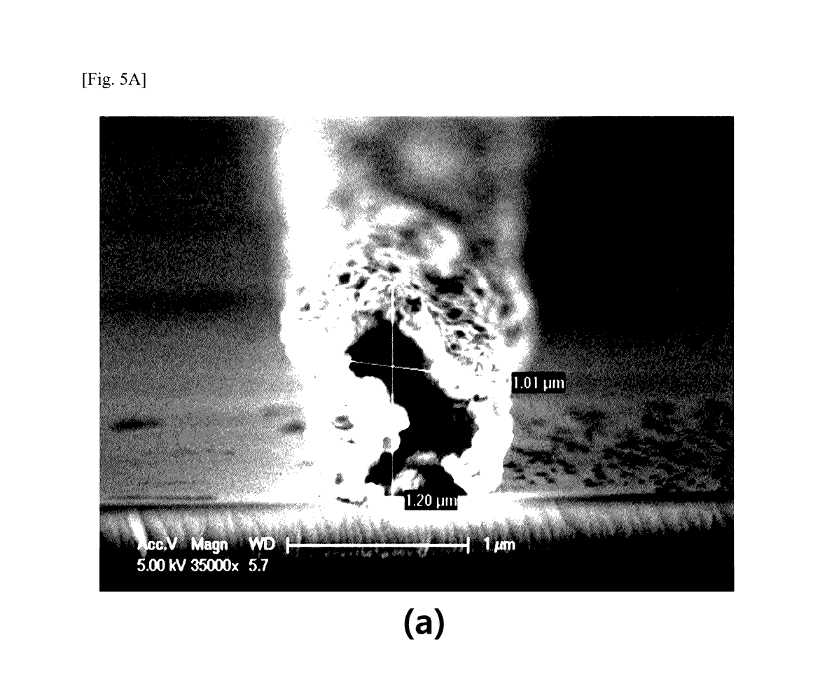

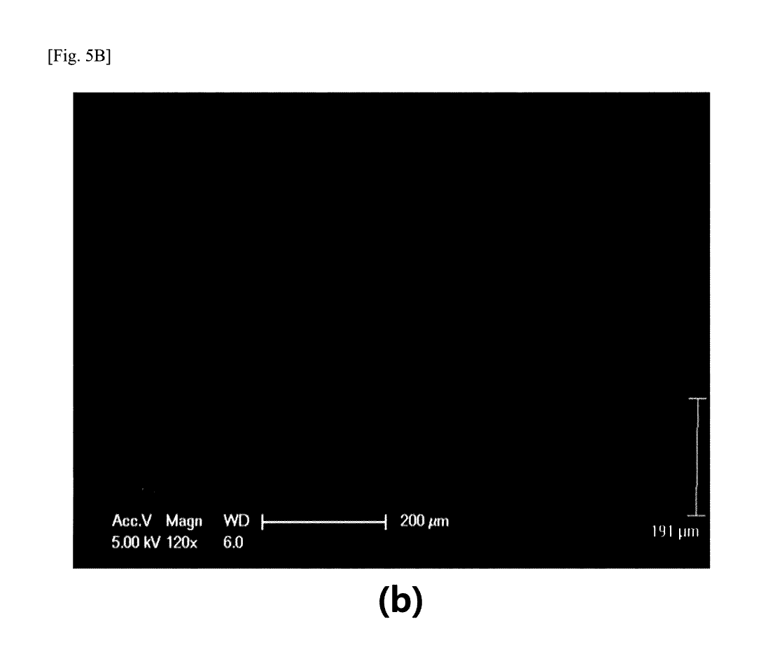

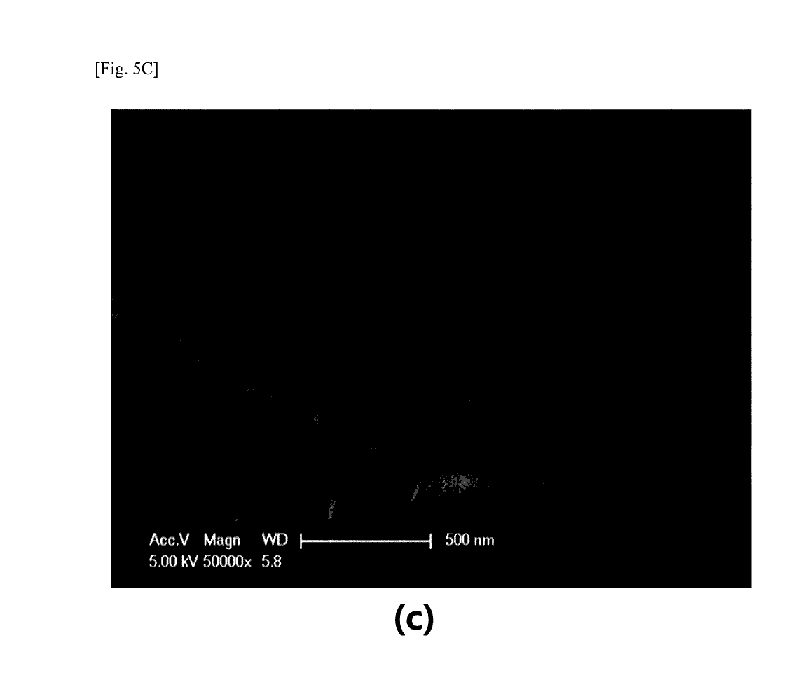

FIG. 5 illustrates the scanning electron microscope (SEM) images and an EDS ingredient analysis result of the copper nanofiber according to Fabrication Example 1 of the present invention.

FIG. 5 illustrates the scanning electron microscope (SEM) images and an EDS ingredient analysis result of a copper nanofiber formed by heat-treating for one or two hours in a 300° C. CVD chamber in which hydrogen gas is flowed at a flow rate of 100 sccm.

FIG. 5a is an SEM image illustrating the cross section of the copper nanofiber, FIG. 5b illustrates an SEM image of the copper nanofiber electrode array according to Fabrication Example 1 of the present invention, and FIG. 5c illustrates an SEM image of the copper nanofiber. In addition, FIG. 5d illustrates an EDS analysis result.

Referring to FIG. 5a, it can be confirmed that the cross section of the copper nanofiber according to Fabrication Example 1 of the present invention is uniform. Referring to FIG. 5b, it can be confirmed that the copper nanofiber electrode array according to Fabrication Example 1 of the present invention is uniformly aligned in a horizontal direction. Referring to FIG. 5c, it can be confirmed that the copper nanofiber according to Fabrication Example 1 of the present invention is uniformly formed in a straight line shape. Referring to FIG. 5d, it can be confirmed that the nanofiber according to Fabrication Example 1 of the present invention nanofiber includes copper. In addition, it can be confirmed that a peak with respect to oxygen therein is remarkably smaller, compared to that of FIG. 4d.

Accordingly, it can be confirmed that the copper oxide nanograins of the copper oxide nanofiber are reduced into copper nanograins by the heat treatment, and thus, a copper nanofiber composed of the copper nanograins is formed.

As a result, it can be confirmed that the copper nanofiber according to Fabrication Example 1 of the present invention is uniformly aligned and formed in a straight line shape.

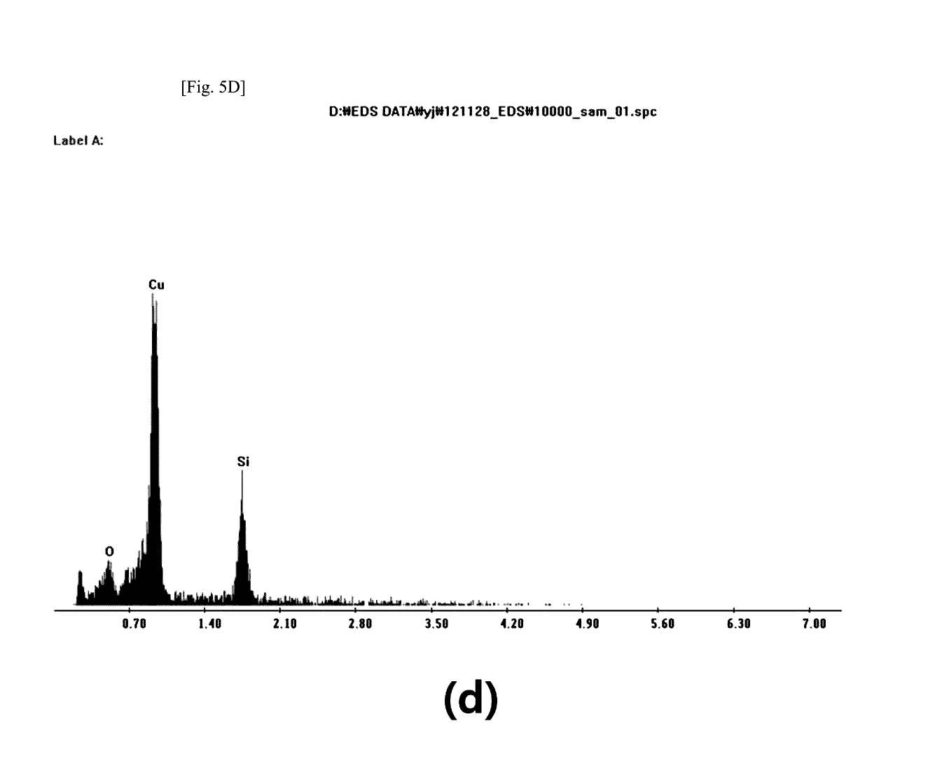

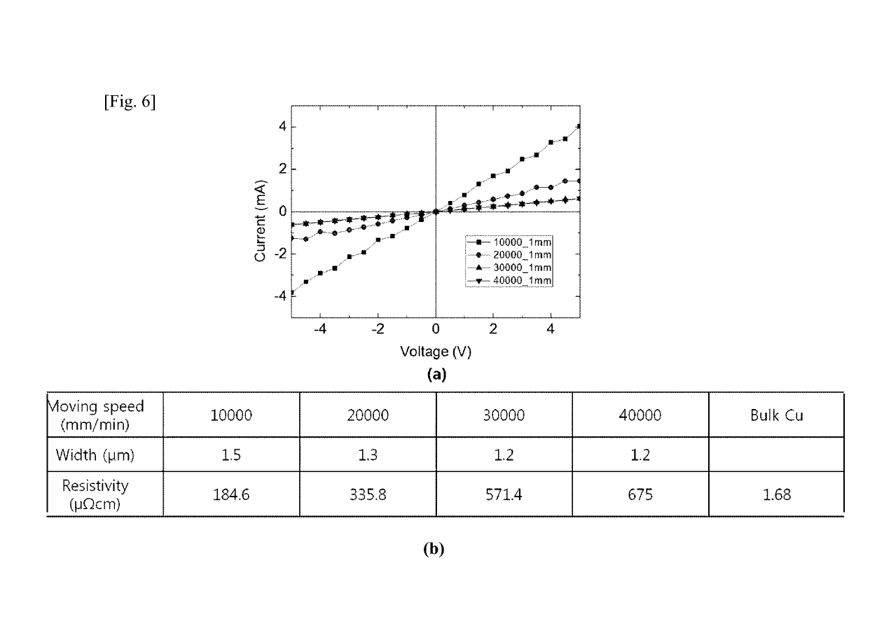

FIG. 6 illustrates a graph showing data values of the widths and resistivity of a copper nanofiber according to Fabrication Example 1 of the present invention, and moving speeds of a collector.

FIG. 6 illustrates that the widths and resistivity of a copper nanofiber formed by heat-treating the copper precursor/organic complex nanofiber for two hours in air by means of a 450° C. furnace and then heat-treating for one hour in a 300° C. CVD chamber in which hydrogen gas is flowed at a flow rate of 100 sccm change according to the moving speed of the collector.

Referring to FIG. 6, it can be confirmed that the width of the copper nanofiber is decreased with an increasing moving speed of the collector. In addition, it can be confirmed that the resistivity increases with a decreasing width of the copper nanofiber.

As a result, it can be confirmed that the resistivity increases with an increasing moving speed of the collector, and thus, a change value in a current dependent upon voltage is decreased.

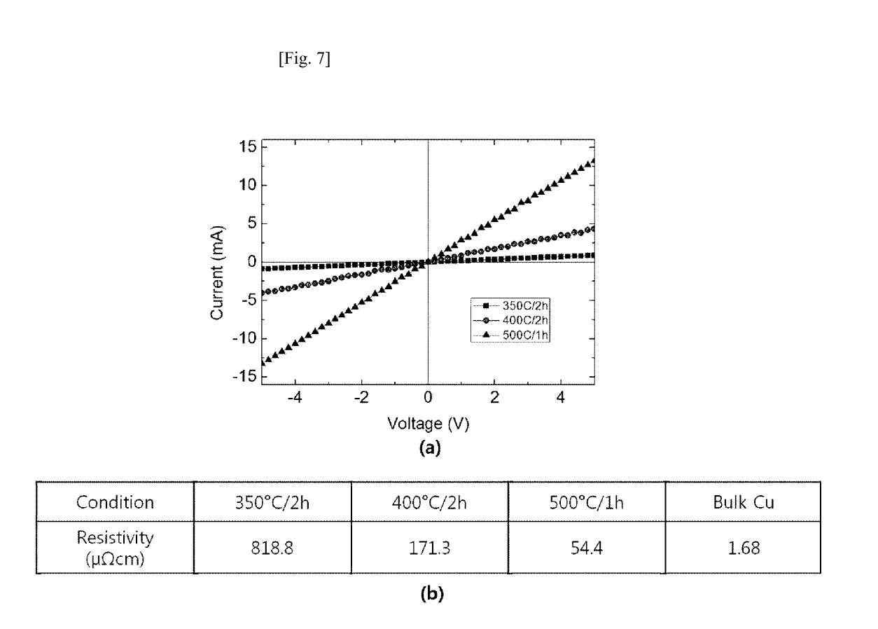

FIG. 7 is a graph showing the change in the resistivity value of a copper nanofiber according to Fabrication Example 1 of the present invention in accordance with heat treatment conditions.

FIG. 7 illustrates that the resistivity of a copper nanofiber with a width of 2 μm formed by heat-treating the copper precursor/organic polymer complex nanofiber for one to two hours in air by means of a furnace at 350° C. to 500° C. and then by heat-treating for one hour in a 300° C. CVC chamber in which hydrogen gas is flowed at a flow rate of 100 sccm changes according to heat treatment conditions.

Referring to FIG. 7, it can be confirmed that the resistivity value decreases with increasing heat treatment temperature.

As a result, it can be confirmed that, in the copper precursor/organic polymer complex nanofiber, the resistivity value decreases with increasing treatment temperature and a change value in a current according to voltage increases.

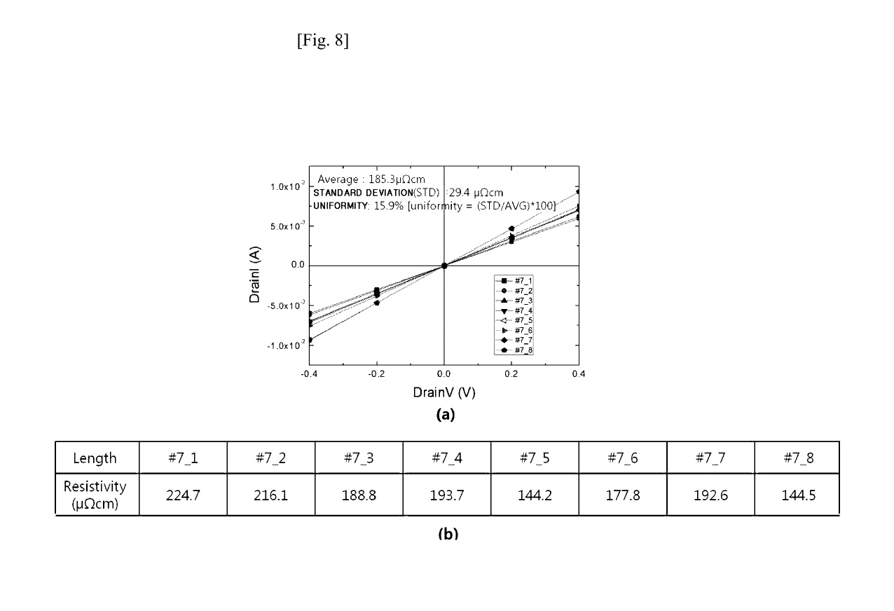

FIG. 8 illustrates a graph showing the uniformity of a copper nanofiber according to Fabrication Example 1 of the present invention.

FIG. 8 illustrates the resistivity uniformity of a copper nanofiber formed by heat-treating a copper precursor/organic complex nanofiber for one hour at 450° C. in air by means of a furnace and then heat-treating the same for one hour in a 300° C. CVC chamber in which hydrogen gas is flowed at a flow rate of 100 sccm.

Referring to FIG. 8, it can be confirmed that an average resistivity value is 185.3 μΩcm and a uniform copper nanofiber having a uniformity of 15.9% is formed.

### Fabrication of Silver-Copper Complex Nanofiber Electrode Array

### Fabrication Example 2

A silver precursor (C₂AgF₃O₂, 21% by weight), a copper precursor (C₄CuF₆O₄, 6.25% by weight), and polyvinyl pyrrolidone (PVP) (10% by weight) were dissolved in dimethylformamide and tetrahydrofuran to prepare a precursor/PVP solution. The concentration of a resultant precursor/PVP solution was 31% by weight.

The prepared precursor/PVP solution was contained in the syringe of the electric field aided robotic nozzle printer, and discharged through the nozzle while applying a voltage of about 0.5 kV to the nozzle. Accordingly, an aligned precursor/PVP complex nanofiber pattern was formed on the substrate of the collector moved by the robot stage.

Here, the diameter of the used nozzle was 100 μm, a distance between the nozzle and the collector was 7 mm, and an application voltage was 0.5 kV. A movement interval in a Y-axis direction of the robot stage was 150 μm and a movement interval in an X-axis direction thereof was 15 cm.

Here, the size of the collector was 20 cm×20 cm and the size of the substrate on the collector was 7 cm×7 cm., and the substrate was a silicon (Si) wafer coated with a silicon oxide film (SiO₂) to a thickness of 300 nm.

Subsequently, when the aligned precursor/PVP nanofiber pattern was heat-treated at 350° C. to 500° C. for one or two hours in air by means of a furnace, the PVP organic polymer was pyrolyzed and, at the same time, the silver and copper precursors were reduced into nanograins and copper nanograins, thereby forming a silver-copper complex nanofiber composed of such silver nanograins and copper nanograins.

Accordingly, a silver-copper complex nanofiber electrode array for a transistor having an area of 7 cm×7 cm was fabricated using the method of fabricating a large-area nanofiber electrode array.

Analysis of Characteristics of Silver-Copper Complex Nanofiber Electrode Array

To analyze the electrical characteristics of the copper nanofiber formed on the SiO₂/Si substrate (the silicon wafer formed by coating a silicon oxide film to a thickness of 300 nm), gold was thermally evaporated on the silver-copper complex nanofiber fabricated according to Fabrication Example 2 using a metal shadow mask, and then IV characteristics thereof were analyzed using a probe station. Morphological analysis was performed using a scanning electron microscope (SEM).

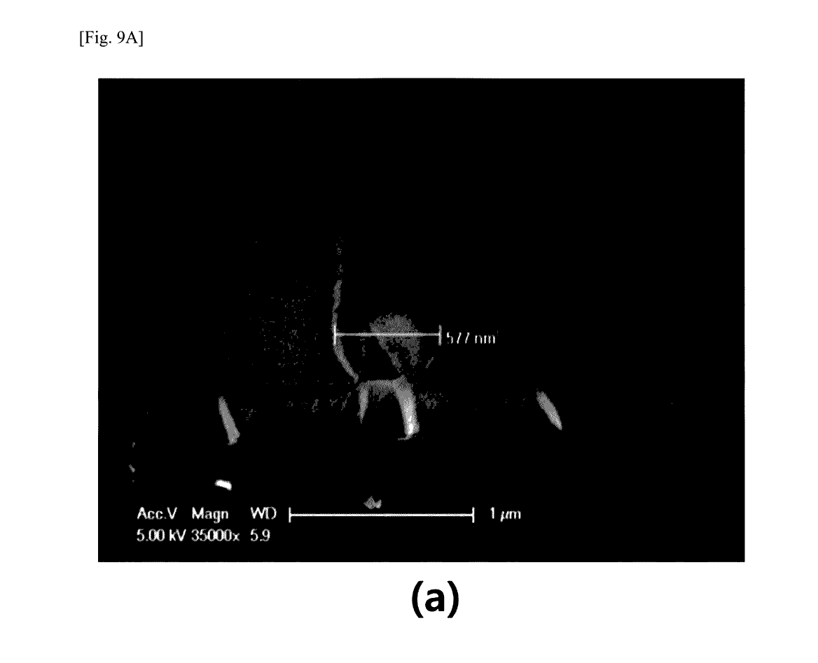

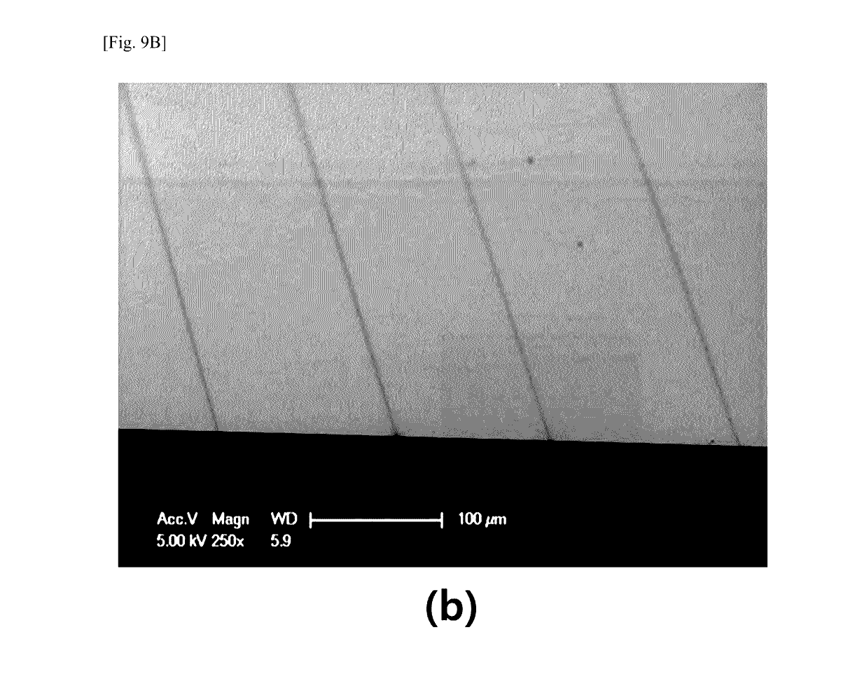

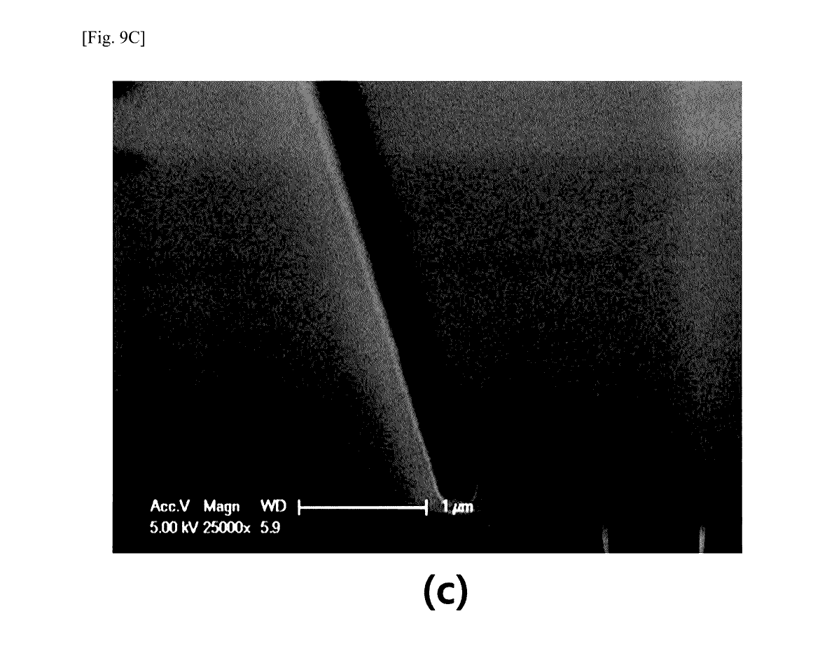

FIG. 9 illustrates SEM images of a silver precursor-copper precursor/organic polymer complex nanofiber according to Fabrication Example 2 of the present invention.

FIG. 9a is an SEM image illustrating the cross section of the silver precursor-copper precursor/organic polymer complex nanofiber, FIG. 9b is an SEM image illustrating an aligned silver precursor-copper precursor/organic polymer complex nanofiber array, and FIG. 9c is an SEM image illustrating the silver precursor-copper precursor/organic polymer complex nanofiber.

Referring to FIG. 9a, it can be confirmed that the diameter of the silver precursor-copper precursor/organic polymer complex nanofiber according to Fabrication Example 1 of the present invention is 577 nm and thus is included within a range of 10 nm to 3000 nm Referring to FIG. 9b, it can be confirmed that the silver precursor-copper precursor/organic polymer complex nanofiber array is aligned at a constant interval. Referring to FIG. 9c, it can be confirmed that the silver precursor-copper precursor/organic polymer complex nanofiber is uniformly formed in a straight line shape.

As a result, it can be confirmed that the metal precursor/organic polymer complex nanofiber of the present invention has a diameter of 10 nm to 3000 nm and is uniformly formed. In addition, it can be confirmed that, upon the formation of the pattern, the nanofiber is horizontally aligned at a constant interval.

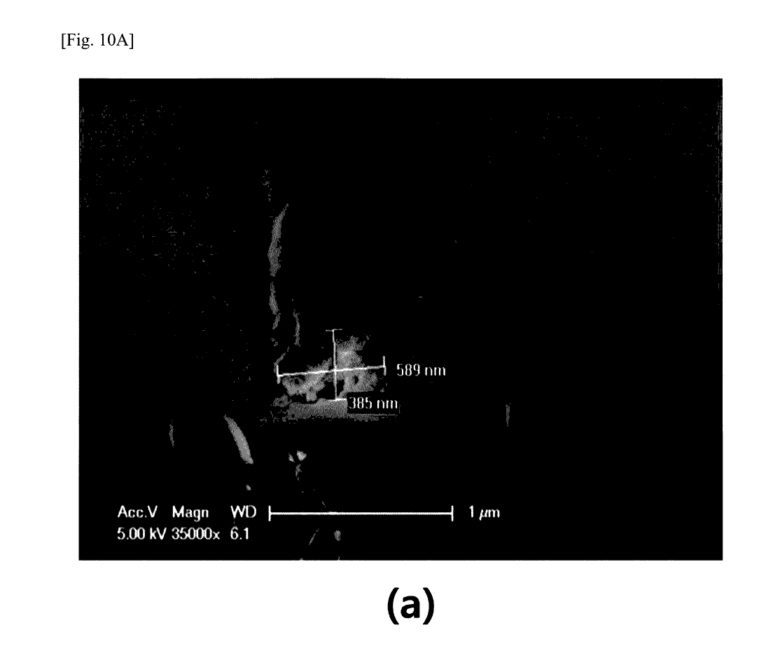

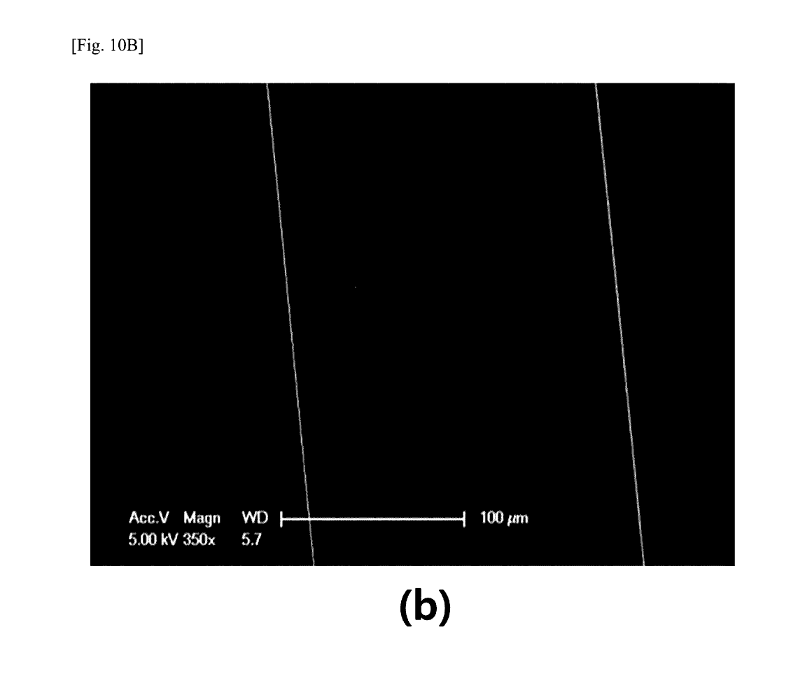

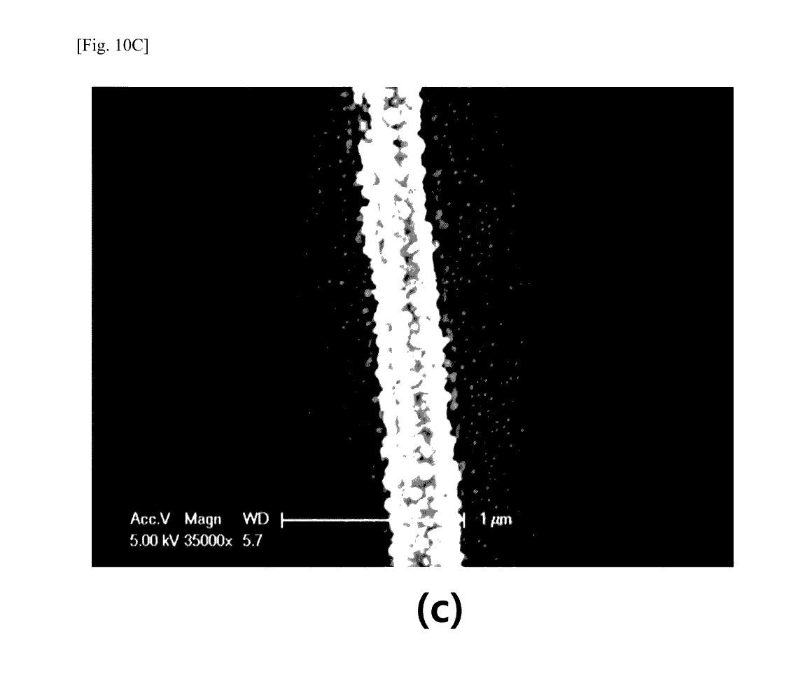

FIG. 10 illustrates SEM images of a silver-copper nanofiber according to Fabrication Example 2 of the present invention.

FIG. 10a is an SEM image illustrating the cross section of the silver-copper nanofiber according to Fabrication Example 2 of the present invention, FIG. 10b is an SEM image illustrating the silver-copper nanofiber array according to Fabrication Example 2 of the present invention, and FIG. 10c is an SEM image illustrating the silver-copper nanofiber according to Fabrication Example 2 of the present invention.

Referring to FIG. 10a, it can be confirmed that the diameter of the silver-copper nanofiber according to Fabrication Example 2 of the present invention is included within a range of 10 nm to 3000 nm Referring to FIG. 10b, it can be confirmed that the silver-copper nanofiber array is uniformly aligned at a constant interval after being heat-treated. Referring to FIG. 10c, it can be confirmed that the silver-copper nanofiber is clearly formed in a straight line shape.

As a result, it can be confirmed that, when the silver precursor-copper precursor/organic polymer complex nanofiber is heat-treated, the organic polymer is pyrolyzed and thus a silver-copper nanofiber is formed. The silver-copper nanofiber is also uniformly formed in a straight line shape and the nanofiber is aligned as a uniform array at a constant interval.

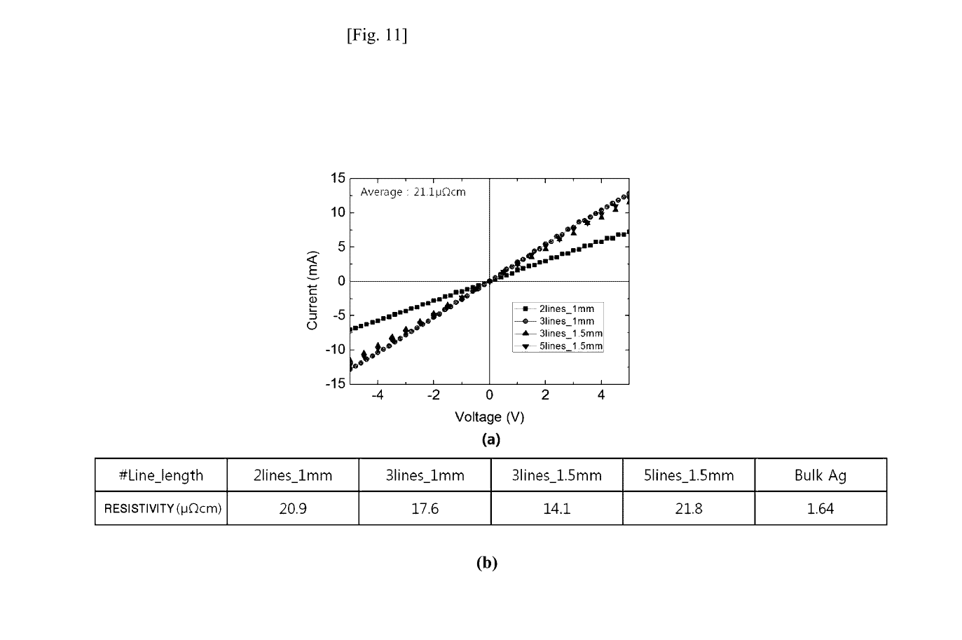

FIG. 11 illustrates an IV characteristic curve and the resistivity of a silver-copper nanofiber according to Fabrication Example 2 of the present invention.

Referring to FIG. 11, as a result of measuring the resistivity of the silver-copper complex nanofiber electrode, an average resistivity value was 21.1 μΩcm.

### Fabrication of Platinum Nanofiber Electrode Array

### Fabrication Example 3

A platinum precursor (H₂PtCl₆6H₂O, 16.5% by weight) and polyvinyl pyrrolidone (PVP) (9% by weight) were dissolved in dimethylformamide and ethanol to prepare a precursor/PVP solution. The concentration of a resultant precursor/PVP solution was 23% by weight. The prepared precursor/PVP solution was contained in a syringe of an electric field aided robotic nozzle printer, and discharged from a nozzle while applying a voltage of about 0.5 kV to the nozzle. An aligned precursor/PVP complex nanofiber pattern was formed on a substrate of a collector moved by a robot stage.

Here, the diameter of the used nozzle was 100 μm, a distance between the nozzle and the collector was 6 mm, and an application voltage was 0.4 kV. A movement interval in a Y-axis direction of a robot stage was 200 μm and a movement interval in an X-axis direction thereof was 15 cm. The size of the collector was 20 cm×20 cm and the size of the substrate on the collector was 7 cm×7 cm. The substrate was a silicon (Si) wafer coated with a silicon oxide film (SiO₂) to a thickness of 300 nm.

When the aligned precursor/PVP nanofiber pattern was heat-treated at 350° C. to 450° C. for one to two hours in air by means of a furnace, the PVP organic polymer was decomposed and, at the same time, the platinum precursor was reduced into platinum, thereby forming a platinum nanofiber.

Accordingly, a platinum nanofiber electrode array having an area of 7 cm×7 cm for a transistor was fabricated.

### Fabrication of Gold Nanofiber Electrode Array

### Fabrication Example 4

A gold precursor (HAuCl₄, 18% by weight) and polyvinyl pyrrolidone (PVP) (10% by weight) were dissolved in dimethylformamide and ethanol to prepare a precursor/PVP solution. The concentration of a resultant precursor/PVP solution was 25% by weight. The prepared precursor/PVP solution was contained in a syringe of an electric field aided robotic nozzle printer, and discharged from a nozzle while applying a voltage of about 0.5 kV to the nozzle. An aligned precursor/PVP complex nanofiber pattern was formed on a substrate of a collector moved by a robot stage.

Here, the diameter of the used nozzle was 100 μm, a distance between the nozzle and the collector was 7.5 mm, and an application voltage was 0.5 kV. A movement interval in a Y-axis direction of a robot stage was 200 μm and a movement interval in an X-axis direction thereof was 15 cm. The size of the collector was 20 cm×20 cm and the size of the substrate on the collector was 7 cm×7 cm. The substrate was a silicon (Si) wafer coated with a silicon oxide film (SiO₂) to a thickness of 300 nm.

When the aligned precursor/PVP nanofiber pattern was heat-treated at 350° C. to 450° C. for one to two hours in air by means of a furnace, the PVP organic polymer was decomposed and, at the same time, the gold precursor was reduced into gold nanograins, thereby forming a gold nanofiber composed of such gold nanograins. Accordingly, a gold nanofiber electrode array having an area of 7 cm×7 cm for a transistor was fabricated.

### Fabrication of Organic Field-Effect Transistor Including Copper Nanofiber Electrode Array

### Fabrication Example 5

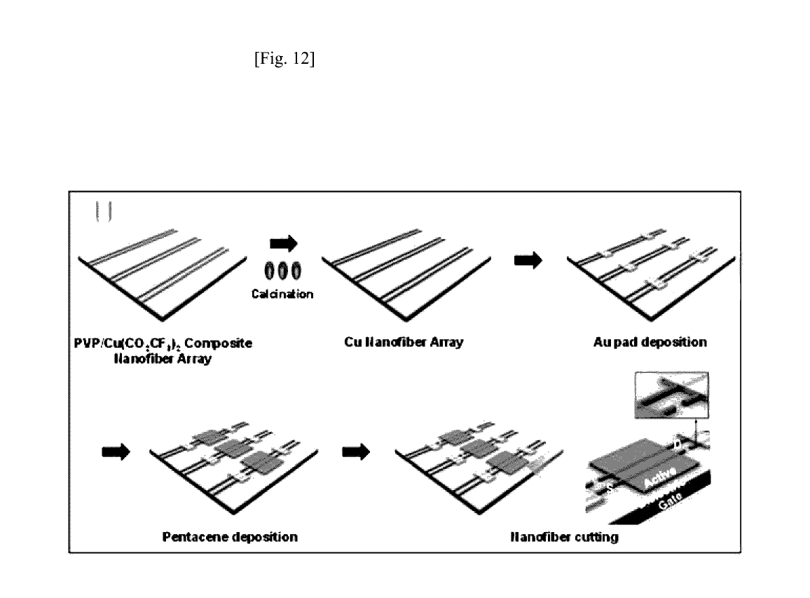

According to a process illustrated as a schematic diagram in FIG. 12, an organic field-effect transistor including a copper nanofiber electrode array was fabricated.

FIG. 12 illustrates a schematic fabrication diagram of an organic field-effect transistor according to another embodiment of the present invention.

Referring to FIG. 12, the copper precursor/organic polymer nanofiber is printed in two lines at an interval of 150 micrometers on a silicon oxide substrate with a thickness of 300 nm as in Fabrication Example 1 and is subjected to two-step heat treatment, thereby forming a copper nanofiber. Such a two-line copper nanofiber was repeatedly formed on the substrate, thereby forming a copper nanofiber array.

Subsequently, since a probe tip cannot directly contact the copper nanofibers, an Au contact pad was deposited to a thickness of about 150 nm for contact.

In addition, to contact the two-line copper nanofiber, a pentacene semiconductor layer was deposited to a thickness of 50 nm, thereby fabricating an organic field-effect transistor.

Here, since the continuously connected copper nanofiber cannot be used as source/drain electrodes for a device, one end of the nanofiber was cut, thus completing a device.

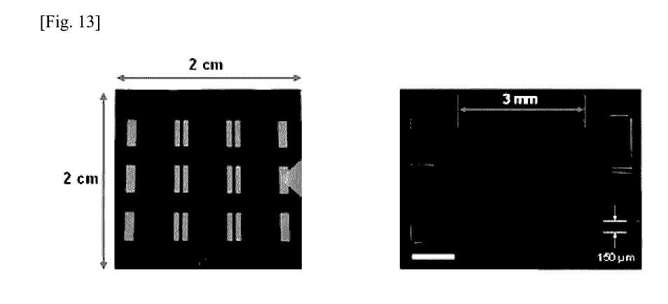

FIG. 13 illustrates images of an organic field-effect transistor according to Fabrication Example 5 of the present invention.

Referring to FIG. 13, nine organic field-effect transistor arrays were fabricated on a silicon wafer with a size of 2×2 cm according to Fabrication Example 5. Here, the length and width of a channel are 150 μm and 3 mm, respectively.

Analysis of Characteristics of Organic Field-Effect Transistor Including Copper Nanofiber Electrode Array

To analyze the electrical characteristics of the organic field-effect transistor including the copper nanofiber electrode array, the transistor fabricated in Fabrication Example 5 was used.

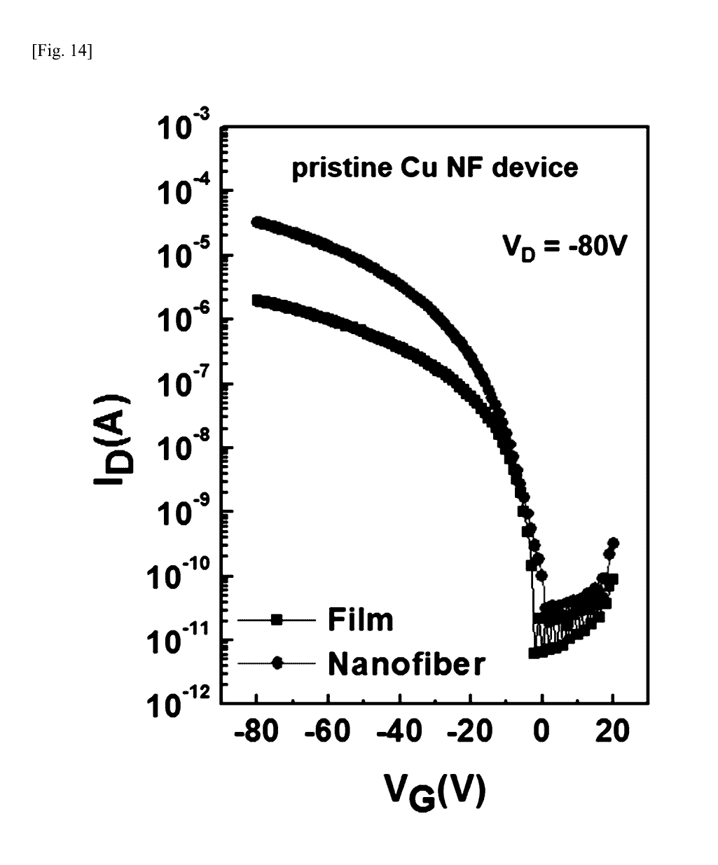

FIG. 14 is a graph showing the transfer curve characteristic of an organic field-effect transistor according to Fabrication Example 5 of the present invention. Here, a drawing inserted into the graph of FIG. 14 is a sectional view of the transistor fabricated according to Fabrication Example 5.

Referring to FIG. 14, the organic field-effect transistor according to Fabrication Example 5 has a field-effect hole mobility of about 0.13 cm⁻²·V⁻¹·s⁻¹ and an on/off current ratio of 7.46×10⁶.

Here, the performance of the transistor using the copper nanofiber electrode according to Fabrication Example 5 was compared to that of a transistor using a copper film electrode fabricated according to a conventional vacuum deposition process, instead of the copper nanofiber electrode.

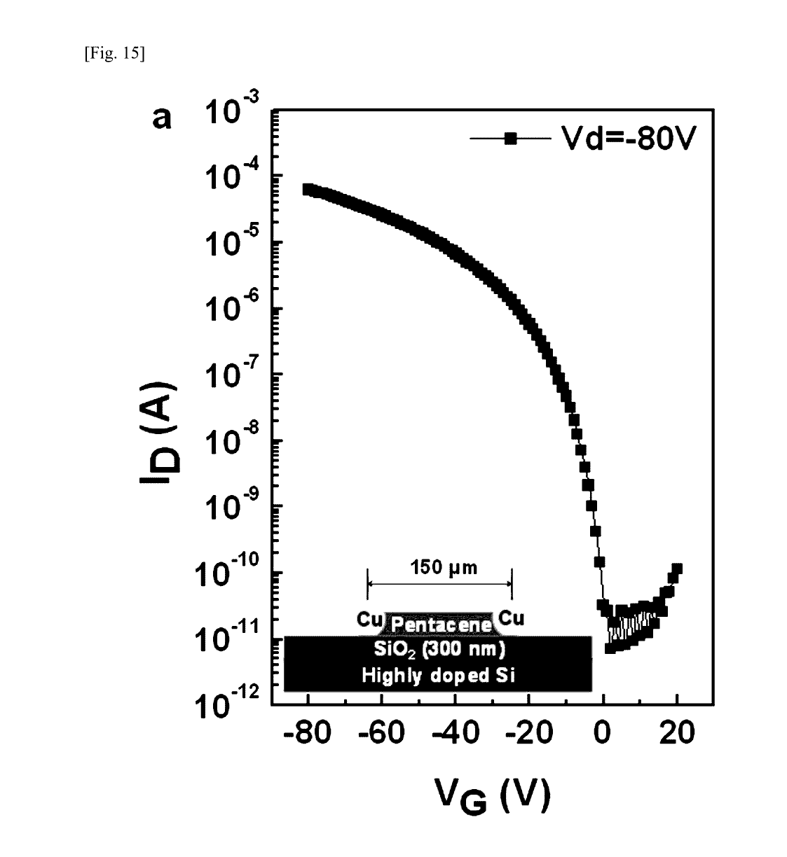

FIG. 15 illustrates an IV characteristic curve of an organic field-effect transistor according to Fabrication Example 5 of the present invention.

Referring to FIG. 15, it can be confirmed that the organic field-effect transistor according to Fabrication Example 5 has a field-effect hole mobility of about 0.13 cm²·V⁻¹·s⁻¹ and the field-effect hole mobility of the transistor having the copper film electrode fabricated according to a conventional vacuum deposition process is about 0.006 cm²·V⁻¹·s⁻¹.

Accordingly, it can be confirmed that the transistor having the copper nanofiber electrode according to the present invention exhibits excellent performance, compared to the transistor having the copper film electrode fabricated according to a conventional vacuum deposition process.

The present invention has been described in more detail with reference to the preferred examples. These examples are provided for illustrative purposes only and should not be construed as limiting the scope and spirit of the present invention and are obvious to those of ordinary skill in the art to which the present invention pertains. In addition, those of ordinary skill in the art may carry out a variety of applications and modifications based on the foregoing teachings within the scope of the present invention, and these modified embodiments may also be within the scope of the present invention.

[Description of Symbols]

| | |
|---|---|
| 10: STORAGE DEVICE | 20: DISCHARGE REGULATOR |
| 30: NOZZLE | 40: VOLTAGE APPLICATION |
| | DEVICE |
| 50: COLLECTOR | 51: GROUNDING DEVICE |
| 60: ROBOT STAGE | 61: BASE PLATE |
| 70: MICRO DISTANCE | 71: JOG |
| CONTROLLER | |

1. A method of fabricating a large-area metal nanofiber electrode array using aligned metal nanofiber, the method comprising:
a step of preparing a metal precursor/organic polymer complex solution by mixing a metal precursor and an organic polymer with distilled water or an organic solvent;
a step of forming an aligned metal precursor/organic polymer complex nanofiber pattern with a continuously connected shape on a substrate by injecting the metal precursor/organic polymer complex solution into a nozzle of an electric field aided robotic nozzle printer and applying an electric field thereto and, accordingly, moving the substrate when a solidified nanofiber with a continuously connected shape is charged while perpendicularly discharging the metal precursor/organic polymer complex solution toward the substrate when the metal precursor/organic polymer complex solution forms a Taylor cone at an end of the nozzle; and
a step of forming an aligned metal nanofiber pattern composed of metal nanograins by pyrolyzing the organic polymer through thermal treatment of the aligned metal precursor/organic polymer complex nanofiber pattern and reducing the metal precursor to metal nanograins.

2. The method according to claim 1, wherein, in the step of preparing the metal precursor/organic polymer complex solution, the metal precursor and the organic polymer in a weight ratio of 10:90 to 97:3 are dissolved in distilled water or an organic solvent such that a concentration becomes 1% by weight to 50% by weight.

3. The method according to claim 1, wherein, upon the discharging of the metal precursor/organic polymer complex solution, the solution is discharged from a distance of 10 μm to 20 mm perpendicular to the substrate.

4. The method according to claim 1, wherein the step of forming an aligned metal precursor/organic polymer complex nanofiber pattern is performed by means of an electric field aided robotic nozzle printer, wherein the electric field aided robotic nozzle printer comprises:
i) a storage device containing a metal precursor/organic polymer complex solution;
ii) a nozzle for discharging a solution supplied from the storage device;
iii) a voltage application device for applying a high voltage to the nozzle;
iv) a collector for fixing the substrate;
v) a robot stage for horizontally moving the collector;
vi) a micro distance controller for perpendicularly moving the collector; and
vii) a base plate for supporting the collector.

5. The method according to claim 1, wherein a voltage applied to the electric field aided robotic nozzle printer is 0.1 kV to 30 kV.

6. The method according to claim 1, wherein the substrate comprises at least one selected from the group consisting of an insulating material, a metal material, a carbon material, and a conductor/insulating film complex material.

7. The method according to claim 1, wherein the metal precursor comprises at least one selected from the group consisting of a copper precursor, a titanium precursor, an aluminum precursor, a silver precursor, a platinum precursor, a nickel precursor, and a gold precursor.

8. The method according to claim 7, wherein the copper precursor comprises at least one selected from the group consisting of copper acetate, copper acetate hydrate, copper acetylacetonate, copper i-butyrate, copper carbonate, copper chloride, copper chloride hydrate, copper ethylacetoacetate, copper 2-ethylhexanoate, copper fluoride, copper formate hydrate, copper gluconate, copper hexafluoroacetylacetonate, copper hexafluoroacetylacetonate hydrate, copper methoxide, copper neodecanoate, copper nitrate hydrate, copper nitrate, copper perchlorate hydrate, copper sulfate, copper sulfate hydrate, copper tartrate hydrate, copper trifluoroacetylacetonate, copper trifluoromethanesulfonate, and tetraamminecopper sulfate hydrate.

9. The method according to claim 7, wherein the titanium precursor comprises at least one selected from the group consisting of titanium carbide, titanium chloride, titanium ethoxide, titanium fluoride, titanium hydride, titanium nitride, titanium isopropoxide, titanium propoxide, titanium methoxide, titanium oxyacetylacetonate, titanium 2-ethylhexyloxide, and titanium butoxide.

10. The method according to claim 7, wherein the aluminum precursor comprises at least one selected from the group consisting of aluminum chloride, aluminum fluoride, aluminum hexafluoroacetylacetonate, aluminum chloride hydrate, aluminum nitride, aluminum trifluoromethanesulfonate, triethylaluminum, aluminum acetylacetonate, aluminum hydroxide, aluminum lactate, aluminum nitrate hydrate, aluminum 2-ethylhexanoate, aluminum perchlorate hydrate, aluminum sulfate hydrate, aluminum ethoxide, aluminum carbide, aluminum sulfate, aluminum acetate, aluminum acetate hydrate, aluminum sulfide, aluminum hydroxide hydrate, aluminum phenoxide, aluminum fluoride hydrate, aluminum tributoxide, aluminum diacetate, aluminum diacetate hydroxide, and aluminum 2,4-pentanedionate.

11. The method according to claim 7, wherein the silver precursor comprise at least one selected from the group consisting of silver hexafluorophosphate, silver neodecanoate, silver nitrate; silver trifluoromethanesulfonate, silver acetate, silver carbonate, silver chloride, silver perchlorate, silver tetrafluoroborate, silver trifluoroacetate, silver 2-ethylhexanoate, silver fluoride, silver perchlorate hydrate, silver lactate, silver acetylacetonate, silver methanesulfonate, silver heptafluorobutyrate, silver chlorate, silver pentafluoropropionate, and silver hydrogenfluoride.

12. The method according to claim 7, wherein the platinum precursor comprises at least one selected from the group consisting of chloroplatinic acid hexahydrate, dihydrogen hexahydroxyplatinate, platinum acetylacetonate, platinum chloride, platinum chloride hydrate, platinum hexafluoroacetylacetonate, tetraammineplatinum chloride hydrate, tetraammineplatinum hydroxide hydrate, tetraammineplatinum nitrate, tetraammineplatinum tetrachloroplatinate, tetrachlorodiammine platinum, dichlorodiammine platinum, and diammineplatinum dichloride.

13. The method according to claim 7, wherein the nickel precursor comprises at least one selected from the group consisting of hexaamminenickel chloride, nickel acetate, nickel acetate hydrate, nickel acetylacetonate, nickel acetylacetonate hydrate, nickel carbonyl, nickel chloride, nickel chloride hydrate, nickel fluoride, nickel fluoride hydrate, nickel hexafluoroacetylacetonate hydrate, nickel hexafluoroacetylacetonate, nickel hydroxide, nickel hydroxyacetate, nickel nitrate hydrate, nickel perchlorate hydrate, nickel perchlorate, nickel sulfate hydrate, nickel sulfate, nickel tetrafluoroborate hydrate, nickel tetrafluoroborate, nickel trifluoroacetylacetonate hydrate, nickel trifluoroacetylacetonate, nickel trifluoromethanesulfonate, nickel peroxide hydrate, nickel peroxide, nickel octanoate hydrate, nickel carbonate, nickel sulfamate hydrate, nickel sulfamate, and nickel carbonate hydroxide hydrate.

14. The method according to claim 7, wherein the gold precursor comprises at least one selected from the group consisting of chlorocarbonylgold, hydrogen tetrachloroaurate, hydrogen tetrachloroaurate hydrate, chlorotriethylphosphinegold, chlorotrimethylphosphinegold, dimethyl (acetylacetonate)gold, gold (I) chloride, gold cyanide, gold sulfide, and gold chloride hydrate.

15. The method according to claim 1, wherein, in the step of preparing the metal precursor/organic polymer complex solution, the metal precursor/organic polymer complex solution further comprises an auxiliary metal precursor.

16. The method according to claim 15, wherein the auxiliary metal precursor comprises at least one selected from the group consisting of a copper precursor, a titanium precursor, an aluminum precursor, a silver precursor, a platinum precursor, a nickel precursor, and a gold precursor.

17. The method according to claim 1, wherein the organic polymer comprises at least one selected from the group consisting of polyvinylalcohol (PVA), polyvinylacetate (PVAc), poly(p-phenylene vinylene (PPV), polyhydroxyethylmethacrylate (pHEMA), polyethylene oxide (PEO), polystyrene (PS), polycaprolactone (PCL), polyacrylonitrile (PAN), poly(methyl methacrylate) (PMMA), poly(vinylidene fluoride) (PVDF), polyaniline (PANI), polyvinylchloride (PVC), nylon, polyacrylic acid, polychlorostyrene, polydimethylsiloxane, polyetherimide, polyethersulfone, polyalkylacrylate, polyethylacrylate, polyethylvinylacetate, polyethyl-co-vinylacetate, polyethyleneterephthalate, polylactic acid-co-glycolic, acid, polymethacrylate, polymethylstyrene, polystyrenesulfonate, polystyrenesulfonylfluoride, polystyrene-co-acrylonitrile, polystyrene-co-butadiene, polystyrene-co-divinylbenzene, polylactide, polyacrylamide, polybenzimidazole, polycarbonate, polydimethylsiloxane-co-polyethyleneoxide, polyetheretherketone, polyethylene, polyethyleneimine, polyisoprene, polylactide, polypropylene, polysulfone, polyurethane, polyvinylpyrrolidone (PVP), polyphenylenevinylene (PPV), and polyvinylcarbazole (PVK).

18. The method according to claim 1, wherein the step of forming the aligned metal nanofiber pattern by heat-treating the aligned, metal precursor/organic polymer complex nanofiber pattern is canniest out at 50° C. to 900° C. for 5 minutes to 8 hours.

19. The method according to claim 1, wherein, in the step of forming the aligned metal nanofiber pattern by heat-treating the aligned metal precursor/organic polymer complex nanofiber pattern, the heat treatment is carried out one to five times.

20. The method according to claim 1, wherein, in the step of forming the aligned metal nanofiber pattern by heat-treating the aligned metal precursor/organic polymer complex nanofiber pattern, the heat treatment is carried out in air or in a gas atmosphere comprising at least one selected from the group consisting of oxygen, nitrogen, hydrogen, and argon.

21. The method according to claim 1, wherein the metal nanofiber has a diameter of 10 nm to 3000 nm.

22. The method according to claim 1, wherein the metal precursor/organic polymer complex nanofiber pattern is horizontally aligned.

23. The method according to claim 1, wherein the metal precursor/organic polymer complex nanofiber pattern has a grid shape in which patterns are aligned while crossing each other.

24. An organic or inorganic field-effect transistor, comprising a gate electrode, a gate insulating layer, a source electrode, a drain electrode, and an organic or inorganic semiconductor layer, wherein any one electrode of the gate electrode, source electrode, and drain electrode is a metal nanofiber electrode fabricated by the method of fabricating the metal nanofiber electrode array according to claim 1.

25. An organic light-emitting diode, comprising a positive electrode, a light emitting layer, and a negative electrode, wherein the organic light-emitting diode selectively, further comprises an auxiliary electrode layer, a hole injection layer, a hole transport layer, an electron transport layer, an exciton blocking layer, a hole blocking layer, or an electron injection layer, and at least one of the positive and negative electrodes has a grid array of a metal nanofiber electrode fabricated by the method according to claim 1.

26. An organic solar cell, comprising a positive electrode, a photoactive layer, and a negative electrode, wherein the organic solar cell selectively, further comprises an auxiliary electrode layer, a hole extraction layer, an exciton blocking layer, or an electron extraction layer, and at least one of the positive and negative electrodes has a grid array of a metal nanofiber electrode fabricated by the method according to claim 1.
